(19) United States
(12) Patent Application Publication
(10) Pub. No.: US 2025/0372520 A1
(43) Pub. Date: Dec. 4, 2025

(54) POWER DISCRETE PACKAGE HAVING SYMMETRIC PINOUTS AND PROCESS OF IMPLEMENTING THE SAME

(71) Applicant: WOLFSPEED, INC., Durham, NC (US)

(72) Inventors: Ajit R. KANALE, Morrisville, NC (US); Prasanna Obala BHUVANESH, Leander, TX (US); Devarajan BALARAMAN, Apex, NC (US)

(21) Appl. No.: 18/733,442

(22) Filed: Jun. 4, 2024

(51) Int. Cl. H01L 23/528; H01L 23/29; H01L 23/495; H01L 23/532

(52) U.S. Cl. CPC H01L 23/5286; H01L 23/293; H01L 23/49568; H01L 23/528; H01L 23/5283; H01L 23/5329

(57) ABSTRACT

A power package includes an assembly having a first power package side, a second power package side, a third power package side, and a fourth power package side; first power terminals arranged at the first power package side; second power terminals arranged at the second power package side; first signal terminals arranged at the third power package side; second signal terminals arranged at the fourth power package side. The power package in addition includes where a location of the first power terminals at the first power package side is symmetrical with respect to a location of the second power terminals at the second power package side and/or a location of the first signal terminals on third power package side is symmetrical with respect to a location of the second signal terminals on fourth power package side.

### FIELD OF THE DISCLOSURE

The disclosure relates to a power discrete package having symmetric pinouts. The disclosure further relates to a process of implementing a power discrete package having symmetric pinouts.

### BACKGROUND OF THE DISCLOSURE

As will be appreciated by those skilled in the art, power packages are known in various forms. Power packages provide a physical containment for one or more power components, usually power semiconductor devices. However, a configuration of power packages typically limits implementations of the power package.

Accordingly, a power package having an improved configuration is needed.

### SUMMARY OF THE DISCLOSURE

The foregoing needs are met, to a great extent, by the disclosure, wherein a power discrete package having symmetric pinouts and a process of implementing a power discrete package having symmetric pinouts are provided.

In one aspect, a power package includes an assembly having a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first power terminals at the first power package side is symmetrical with respect to a location of the second power terminals at the second power package side.

In one aspect, a power package includes an assembly having a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first signal terminals on third power package side is symmetrical with respect to a location of the second signal terminals on fourth power package side.

In one aspect, a power package includes an assembly having a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first signal terminals on third power package side is symmetrical with respect to one side of third power package side and another side of third power package side. The power package moreover includes where a location of the second signal terminals on fourth power package side is symmetrical with respect to one side of fourth power package side and another side of fourth power package side.

In one aspect, a power package includes an assembly having a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first signal terminals on third power package side is symmetrical with respect to one side of third power package side and another side of third power package side. The power package moreover includes where a location of the second signal terminals on fourth power package side is symmetrical with respect to one side of fourth power package side and another side of fourth power package side.

In one aspect, a power package includes an assembly having a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first signal terminals on third power package side is symmetrical with respect to a location of the second signal terminals on fourth power package side.

In one aspect, a power package includes an assembly having a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where an arrangement and location of the first power terminals is symmetrical about a lateral axis of symmetry with respect to an arrangement and location of the second power terminals.

In one aspect, a power package includes an assembly having a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where an arrangement and location of the first power terminals is symmetrical about a longitudinal axis of symmetry with respect to an arrangement and location of the second power terminals.

In one aspect, a power package includes an assembly having a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where an arrangement and location of the first signal terminals is symmetrical about a longitudinal axis of symmetry with respect to an arrangement and location of the second signal terminals.

In one aspect, a power package includes an assembly having a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where an arrangement and location of the first signal terminals is symmetrical about a lateral axis of symmetry with respect to an arrangement and location of the second signal terminals.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates top views of a power package according to aspects of the disclosure.

FIG. 2 illustrates a bottom view of an exemplary power package according to aspects of the disclosure.

FIG. 3 illustrates an upside down side view of the exemplary power package according to FIG. 2.

FIG. 4 illustrates a top view of an exemplary power die that may be implemented in the power package of FIG. 2.

FIG. 5 illustrates a bottom view of an exemplary power package according to aspects of the disclosure.

FIG. 6 illustrates an upside down side view of the exemplary power package according to FIG. 5; and FIG. 6 also illustrates an upside up side view of the exemplary power package according to FIG. 5.

FIG. 7 illustrates an upside up side view of the exemplary power package according to FIG. 5 arranged on an application.

FIG. 8 is a top view of another exemplary power die that may be implemented in the power package according to aspects of the disclosure.

FIG. 9 is a top view of another exemplary power die that may be implemented in the power package according to aspects of the disclosure.

FIG. 10 is a top view of another exemplary power die that may be implemented in the power package according to aspects of the disclosure.

FIG. 11 illustrates a bottom view of an exemplary power package according to aspects of the disclosure.

FIG. 12 is a top view of another exemplary power die that may be implemented in the power package according to aspects of the disclosure.

FIG. 13 illustrates a bottom view of an exemplary power package according to aspects of the disclosure.

FIG. 14 illustrates a top view of the power package according to FIG. 13.

FIG. 15 illustrates a bottom view of an exemplary power package according to aspects of the disclosure.

FIG. 16 illustrates a top view of the power package according to FIG. 15.

FIG. 17 illustrates a parallel connection of two implementations of the power package according to the aspects of the disclosure.

FIG. 18 illustrates a parallel connection of two implementations of the power package according to the aspects of the disclosure.

FIG. 19 illustrates a common-drain connection of two implementations of the power package according to the aspects of the disclosure.

FIG. 20 is a cross-sectional view of the parallel connection of FIG. 19.

FIG. 21 illustrates a parallel common-source bidirectional configuration of two implementations of the power package according to the aspects of the disclosure.

FIG. 22 illustrates a bottom view of an exemplary power package according to aspects of the disclosure.

FIG. 23 illustrates a further more detailed bottom view of the exemplary power package according to FIG. 22.

FIG. 24 illustrates a further more detailed bottom view of the exemplary power package according to FIG. 22.

FIG. 25 illustrates a cross-sectional view of the exemplary power package according to FIG. 22.

FIG. 26 illustrates a bottom view of an exemplary power package according to aspects of the disclosure.

FIG. 27 illustrates a cross-sectional view of the exemplary power package according to FIG. 26.

### DETAILED DESCRIPTION

The disclosure will now be described with reference to the drawing figures, in which like reference numerals refer to like parts throughout. Aspects of the disclosure advantageously provide a reversible power package and a process of implementing a reversible power package.

The structures and techniques in this disclosure describe a power package with one or more paralleled power semiconductors. With a rise in interest in back-to-back bidirectional switches for high-power applications, the disclosed power package can be used in a variety of topologies including standalone, paralleled, common-source bidirectional, common-drain bidirectional, and/or the like.

Aspects of the disclosed power package may be implemented with a modular and reversible package that allows for significant amounts of modularity and scalability. Aspects of the disclosed power package may be scaled to match industry standard footprints to be compatible with series, parallel, common-source, common-drain, and/or the like interconnections.

Aspects of the disclosed power package may be implemented with a layout and structure of a symmetric pin-out single switch position power package that can be implemented in single-chip or multi-chip configurations with common-source or common-drain connections externally. Aspects of the disclosed power package may be implemented with a layout and structure that may be compatible with top-side cooling and surface mount configurations.

Aspects of the disclosed power package may be implemented with terminal arrangements with signal pins along one axis and power pins along another axis. Aspects of the disclosed power package may be implemented with terminal arrangements with kelvin drain pins for gate driver protection circuitry.

Aspects of the disclosed power package may be implemented with a modular layout that can house multiple device types, devices sizes, and physical arrangements. Aspects of the disclosed power package may be implemented with a scalable structure such that a length and/or width can adapt to a given size to meet footprint requirements and/or to optimize power density.

Aspects of the disclosed power package may be implemented with a scalable structure such that the length and/or width can adapt to optimize heat spreading and thermal performance. Aspects of the disclosed power package may be implemented with a layout and structure to implement additional functionality such as temperature sensors, current sensors, strain sensors, and/or the like.

Aspects of the disclosed power package may be implemented with techniques for realizing a common-source and common-drain bidirectional switch topologies, as well as others, with a single switch package. Aspects of the disclosed power package may be implemented with techniques for paralleling the power packages in standalone configurations, common-source configurations, common-drain configurations, and/or the like.

Increasing demand for power consumption in decreasing form factors for power systems across the globe has led to widespread adoption of silicon carbide (SiC) power semiconductor devices in various package formats with varying pinout configurations.

The vast array of products makes it imperative that power electronics businesses provide circuit boards that may be designed per the particular choice of power semiconductor device with no guarantee of universal compatibility. Aspects of the disclosed power package may implement a discrete package with a symmetric pinout to enable easy placement of power packages on the circuit board irrespective of lateral position and, to some extent, orientation. The symmetric pinout featured in this disclosure may be configured so that the power package is ‘reversible’ from a circuit assembly standpoint. Aspects of the disclosed power package may be referred to as a reversible package, a reversible discrete package, a symmetric package, a symmetric discrete package and/or the like.

The modular and scalable reversible package detailed herein may have the capability to meet the needs of many applications in a way that can be compact and maintain the flexibility of multiple package approaches, while also being able to scale up to house more than one device in a single housing. Aspects of the disclosed power package may also be used to form a topology, or arrangement of devices, in a manner best suited for the target application.

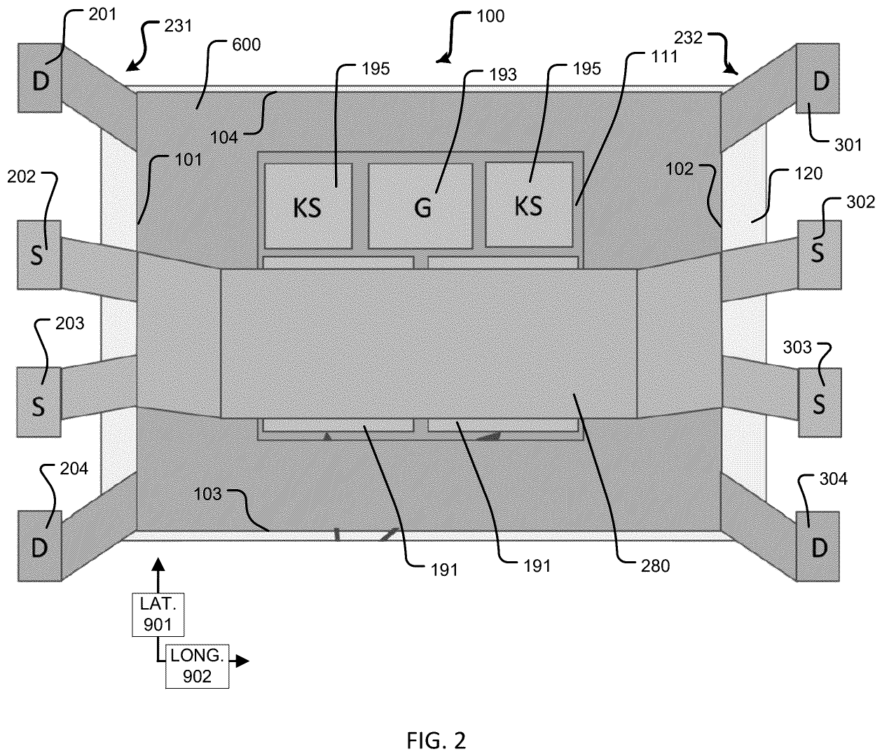

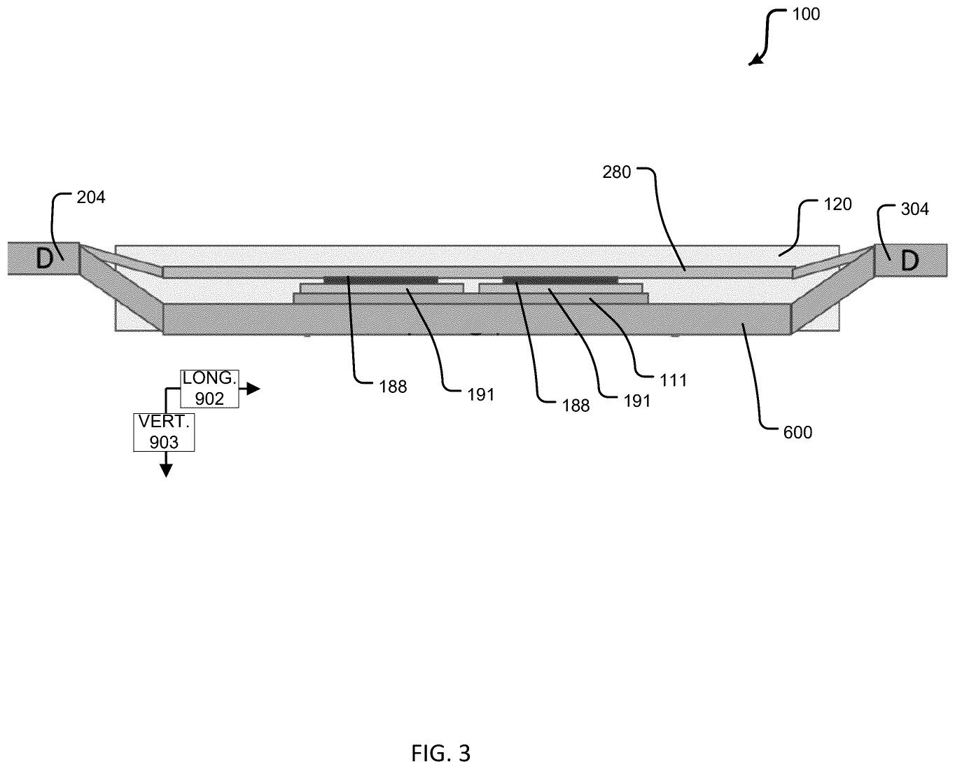

An exemplary structure of the power package as seen from the bottom and side are illustrated in FIG. 2 and FIG. 3. The stack-up inside the power package is detailed in FIG. 3, where the power package is flipped with its top side facing down and bottom side facing up. The top slug may be a metal plate with thick drain legs sticking out towards the bottom side. A power semiconductor die with the drain contact on the bottom of the power semiconductor die can be adhered to the top slug directly using solder or other die attach mechanisms. The source pads on the surface of the power semiconductor die may be provided with risers, to which a thick metal bar is attached. The source bar may also have pinouts that may be pointed towards the bottom side of the power package.

The power package may be implemented as an assembly that may be encapsulated in epoxy, overmolded, overmolded with epoxy, potted, potted with a dielectric material, such as dielectric isolation gels such as Silica, and/or the like.

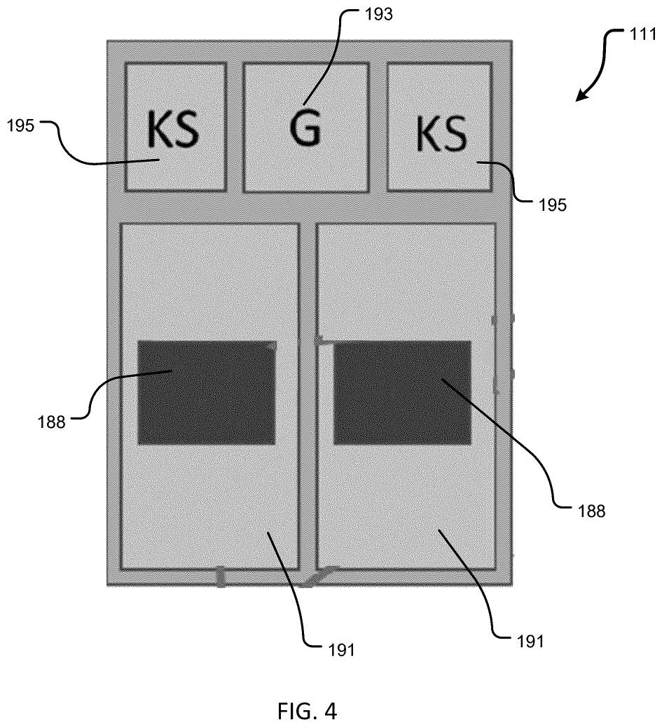

In aspects, the power package may implement the one or more power semiconductor dies structured as shown in FIG. 4, the power package when seen from its bottom side appears as shown in FIG. 2.

In aspects as shown herein including FIG. 2, the power discrete package may implement a symmetric pinout.

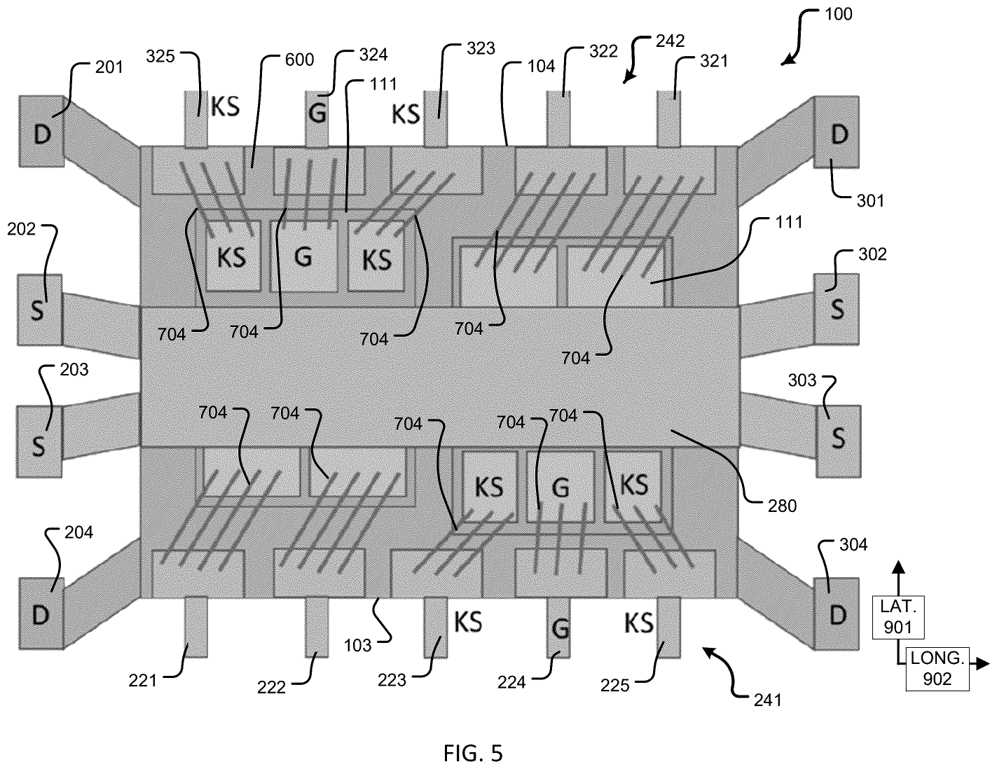

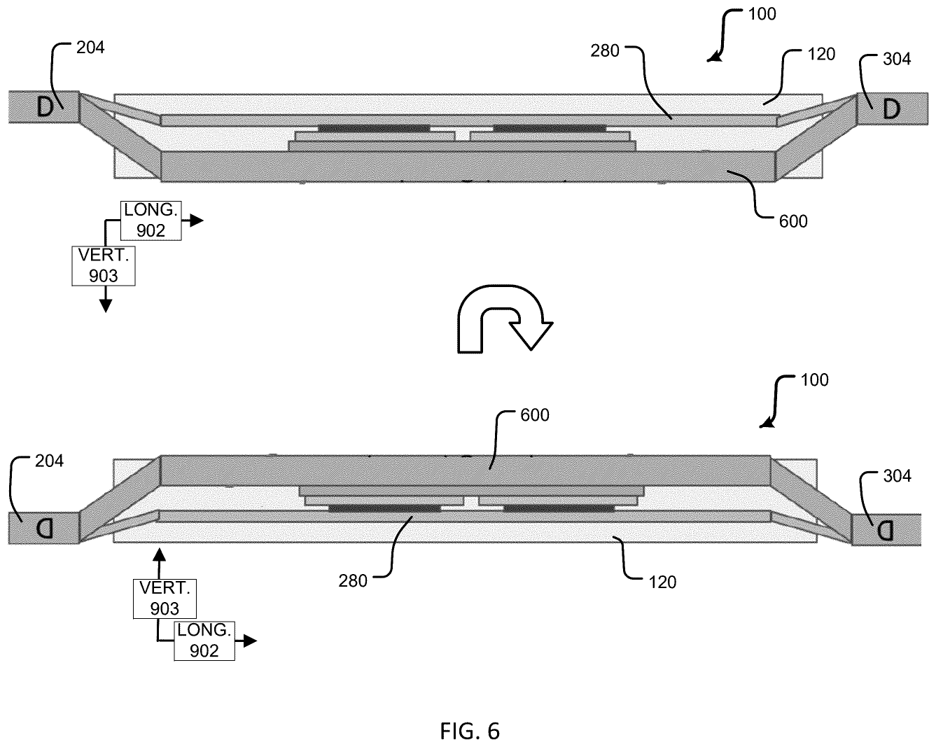

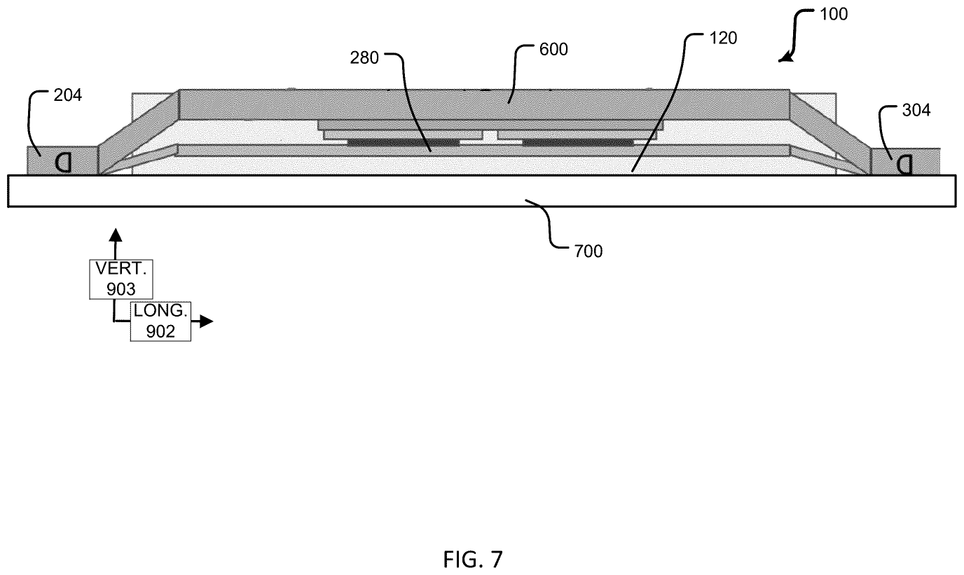

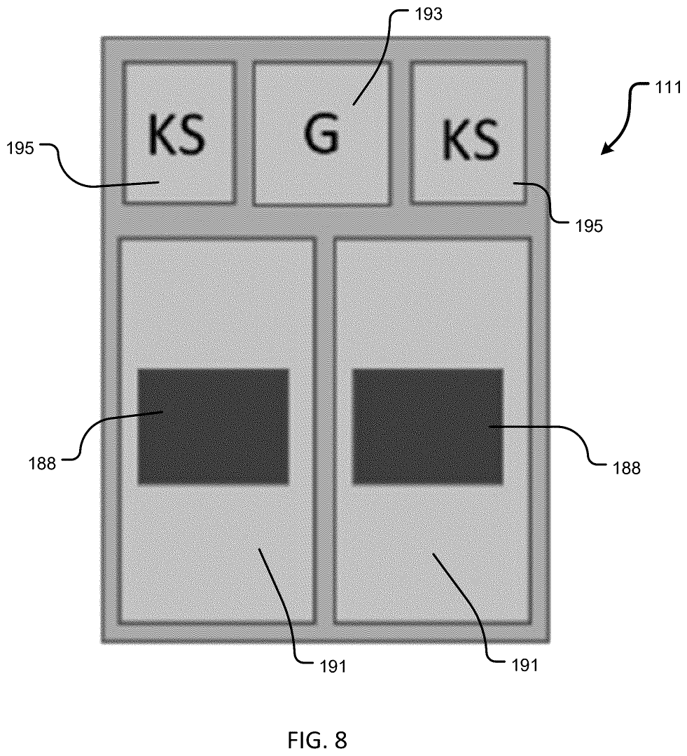

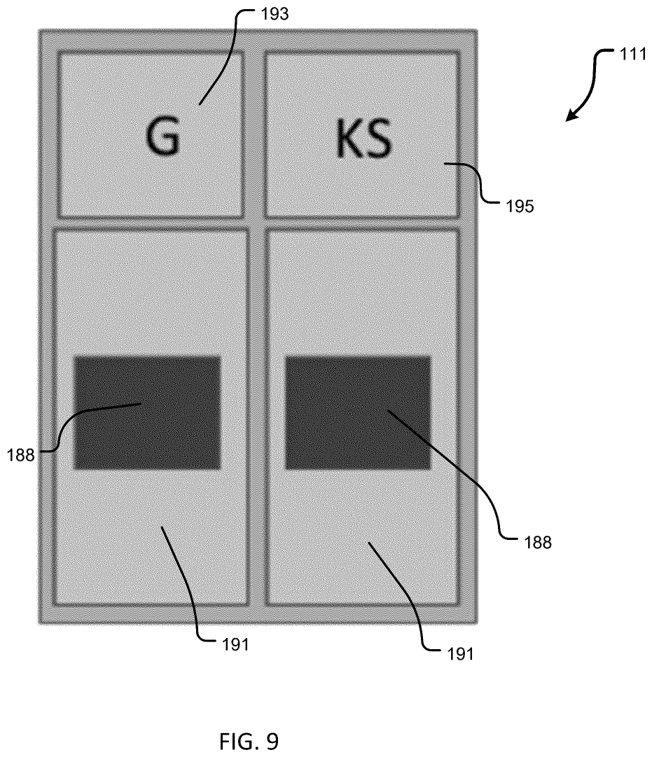

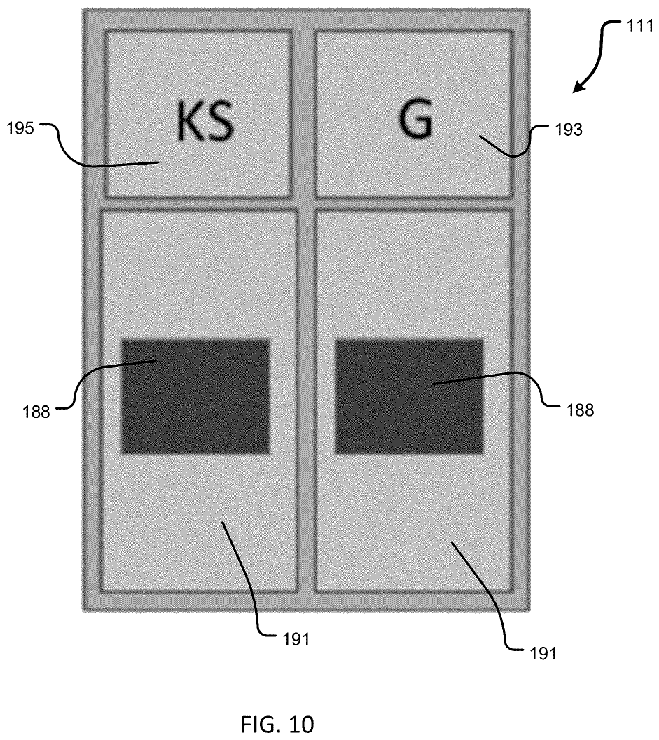

A more detailed internal view of the power package is shown in FIG. 5, FIG. 6, and FIG. 7. The power package cross section when surface mounted on a printed circuit board (PCB) or the like is shown in FIG. 7. The bottom view of the interiors of the power package with power and signal connections is shown in FIG. 5. The power package may implement two parallel power semiconductor dies that may enable a full utilization of all signal pins in this power package implementation. Some of the power semiconductor dies that may be compatible with this package structure are shown in FIG. 8, FIG. 9, and FIG. 10.

FIG. 5 illustrates the power package implemented as a reversible module with symmetric pinout, which is a 3D rendering illustrating exposed wire bonds, and FIG. 6 illustrates the power package encapsulated in silicone potting gel.

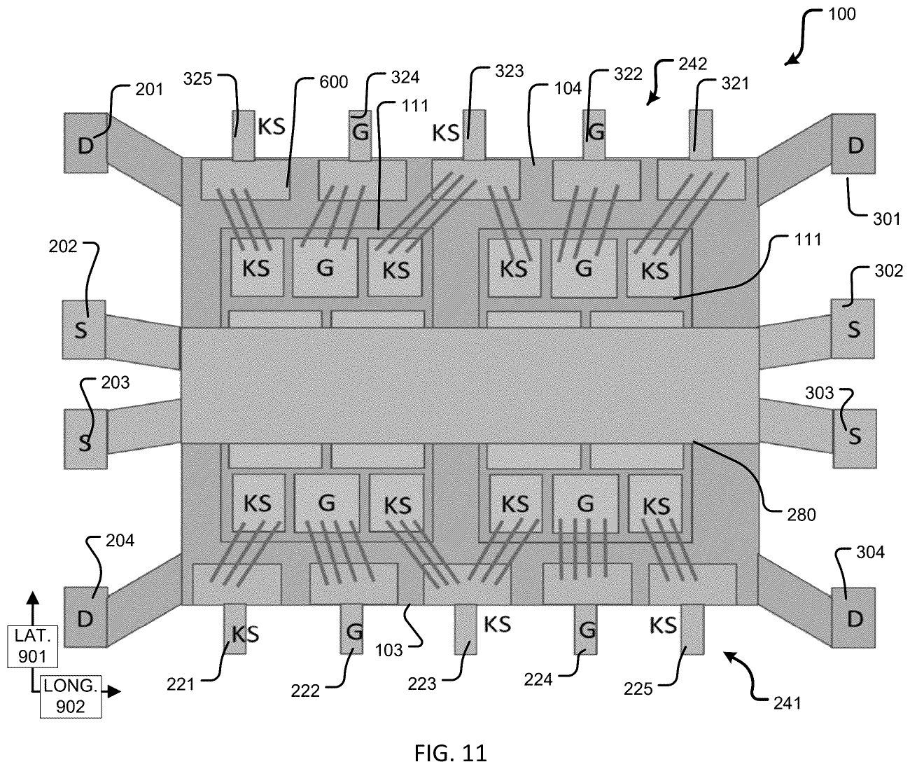

In particular, the symmetry of the power package pinout may be more effectively utilized by semiconductor devices having symmetric signal pads on either side of source contacts. FIG. 11 shows a reversible package populated with power semiconductor devices having dual sets of signal pads. One potential shortcoming may be that the implementation of the power package in FIG. 11 may be that device protection circuits need to tap a high-current power pin to access voltage drop information across the power semiconductor devices, which might require extra protection to prevent current flow from the power terminals into the gate drive circuitry.

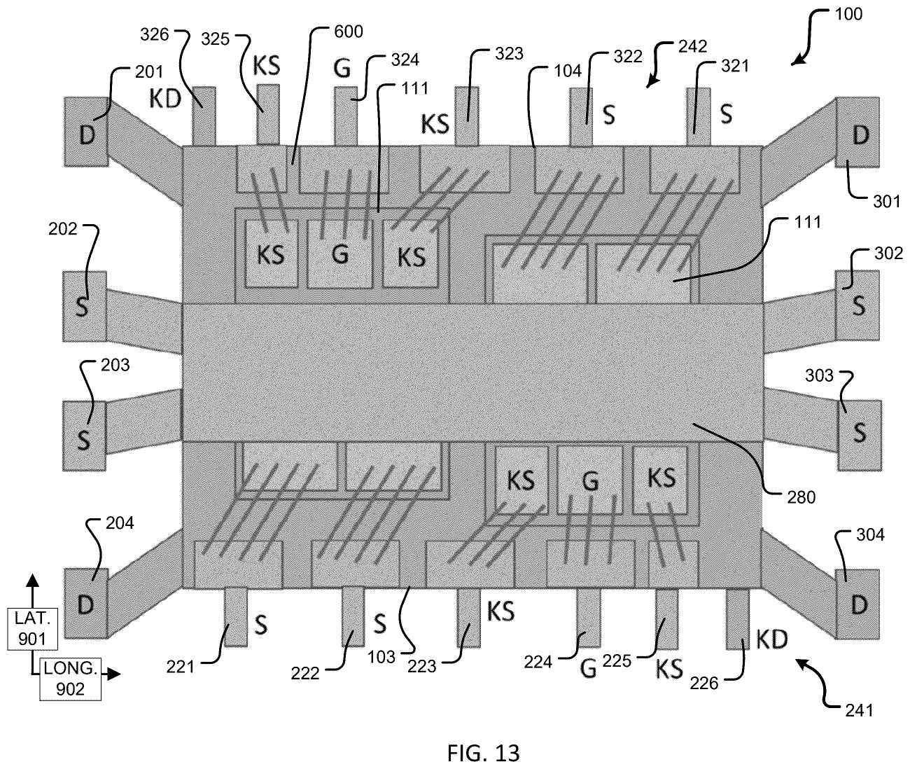

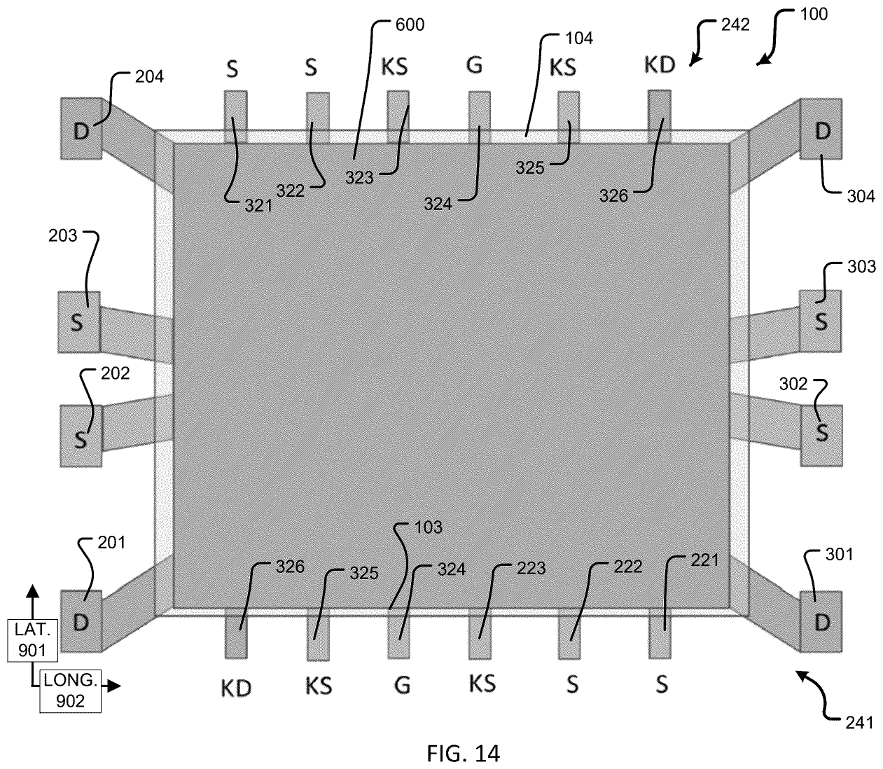

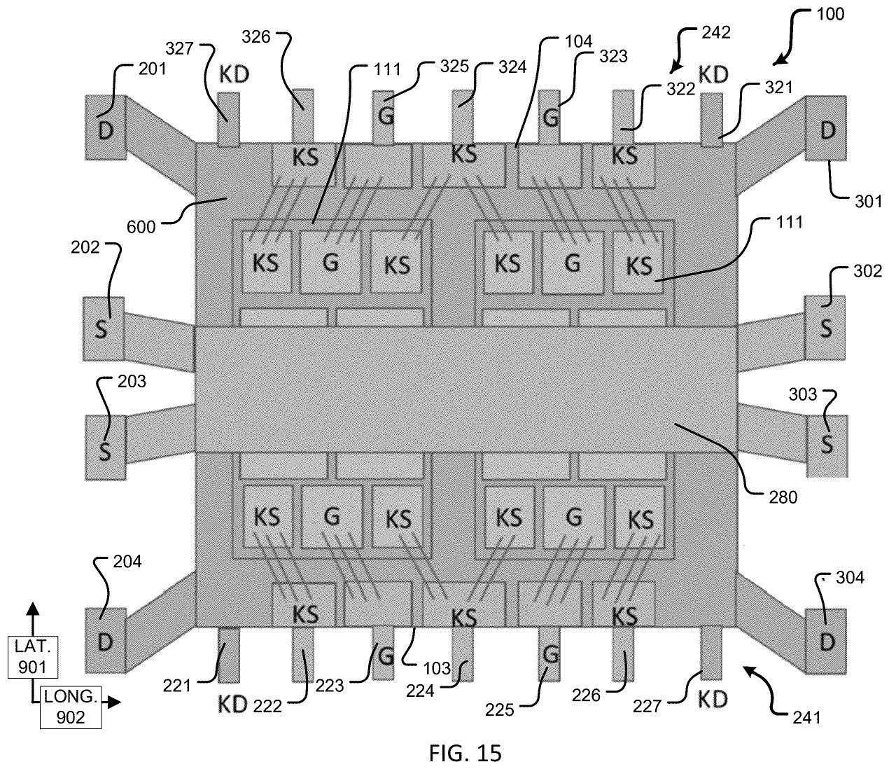

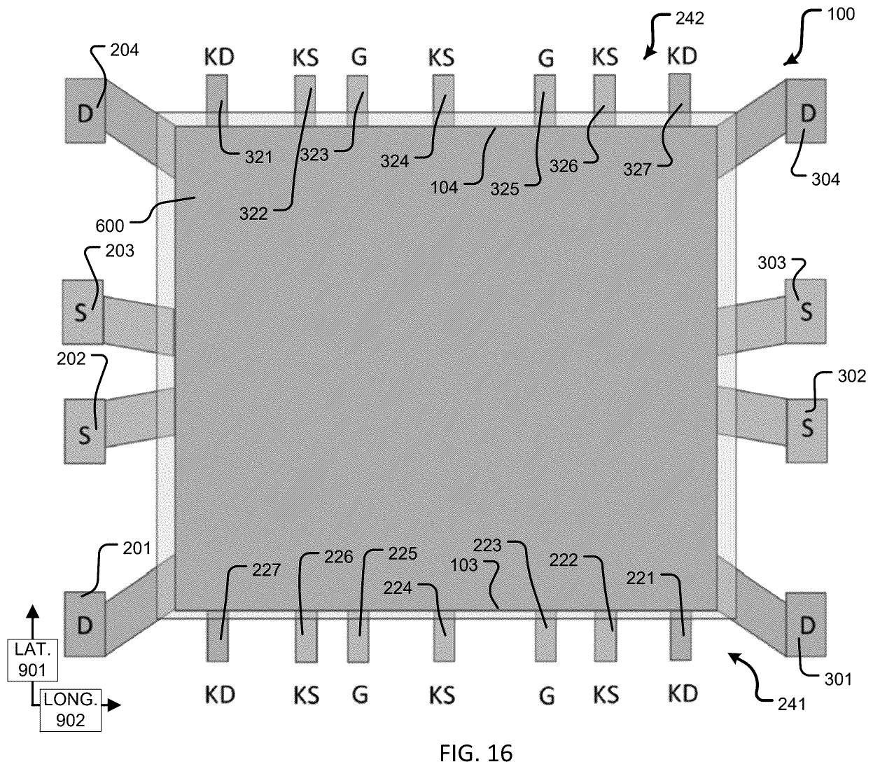

The above shortcoming can be avoided by having a kelvin drain (KD) pin on the signal side of the power package. This implementation is shown in FIG. 13, FIG. 14, FIG. 15, and FIG. 16.

FIG. 13 shows the counterpart of the power package illustrated FIG. 5, FIG. 6, and FIG. 7, but with the kelvin drain (KD) pins on the power package signal side. The inside view of the power package when seen from the bottom is shown in FIG. 13 and the power package view when seen from the top is shown in FIG. 14. In this regard, FIG. 13 and FIG. 14 illustrate an implementation of the power package implemented as a reversible module showing cross sections with kelvin drain connections for the package along with compatible semiconductor device structures.

FIG. 15 and FIG. 16 show a counterpart of the power package of FIG. 11, but with the kelvin drain (KD) pins on the power package signal side. The inside view when seen from the bottom is shown in FIG. 15 and the power package view when seen from the top is shown in FIG. 16.

An advantage of this power package may be the symmetry in the power package pinouts. This reduces human error when placing the power package on a circuit board. The symmetric pinouts result in the same pin connectivity even if it is rotated by 180°.

Additionally, the symmetry allows system engineers to create single-switch, paralleled-switch, common-source, and common-drain topologies with the same discrete package. Some exemplary implementations are shown in the figures. From a commercialization standpoint, this may be beneficial in driving down silicon carbide (SiC) product costs and simplify the circuit design process and/or inventory for customers using these packages.

Furthermore, the presence of a Kelvin drain pin may enable easy implementations of protection circuitry on the gate driver board.

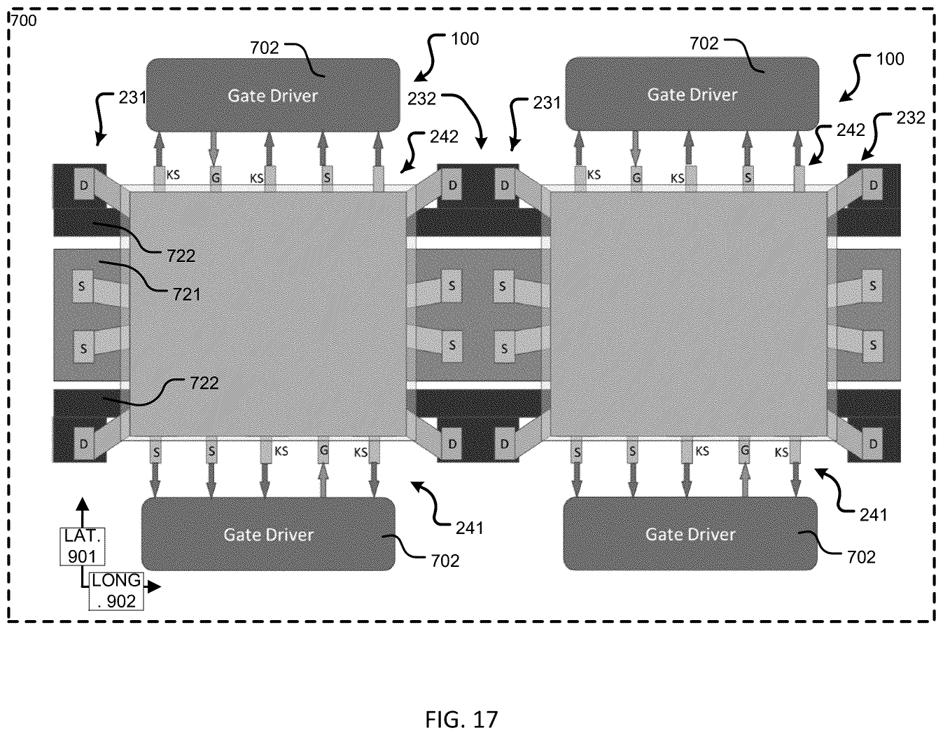

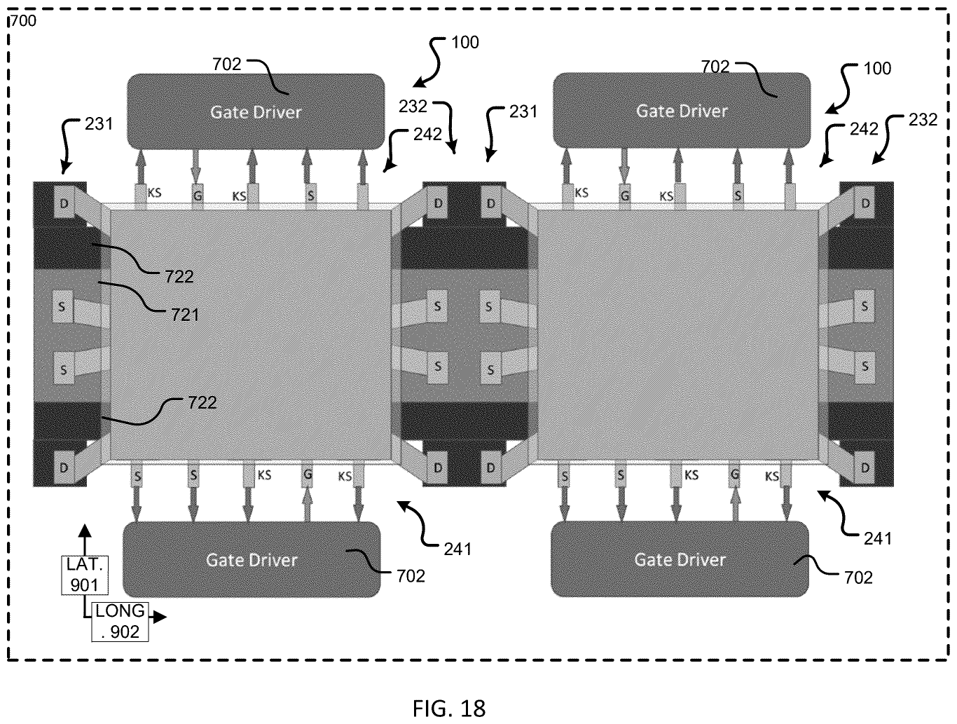

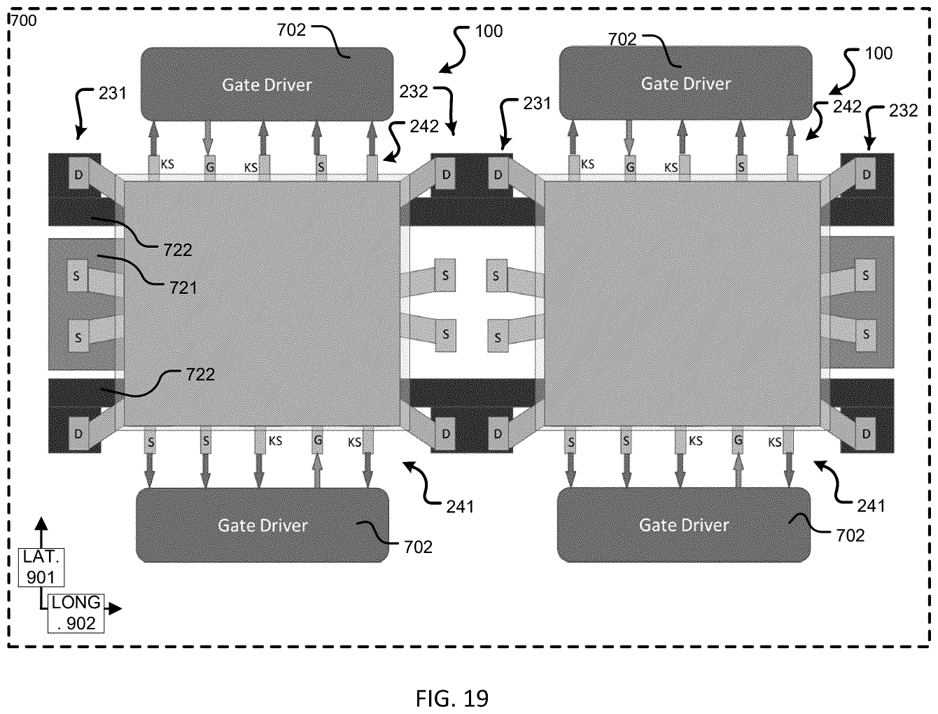

A schematic of two reversible packages connected in parallel is shown in FIG. 17. The power terminals can be directly placed on long power rails, with the gate drive signals being connected from the perpendicular direction on the circuit board. Additionally, the drain rails may be on an inner layer to reduce inductance and allow the top layer space to be better utilized. This implementation is shown in FIG. 18 and FIG. 19.

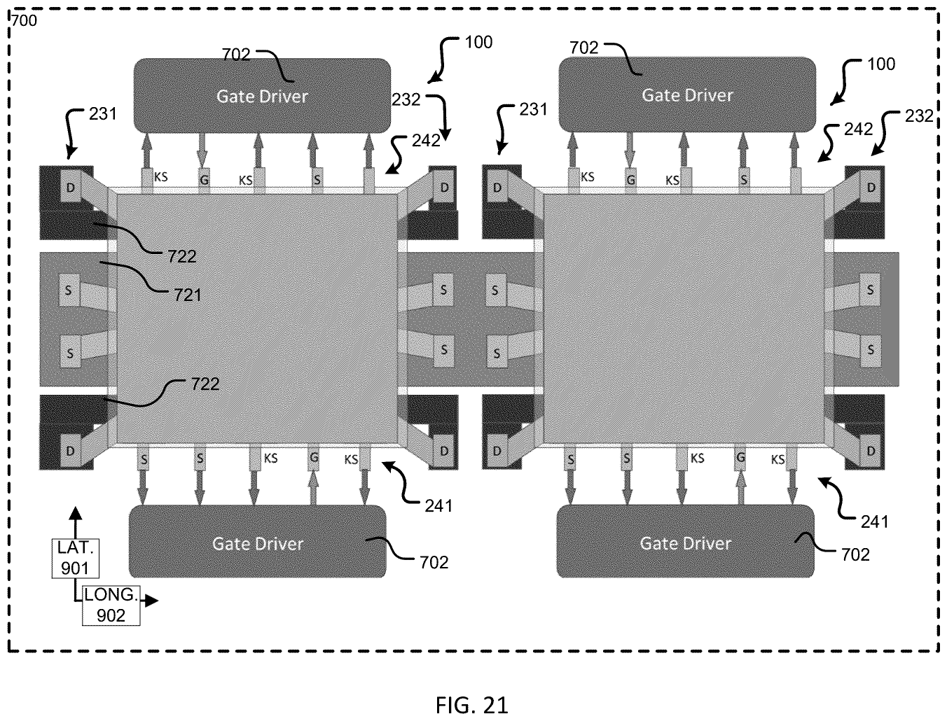

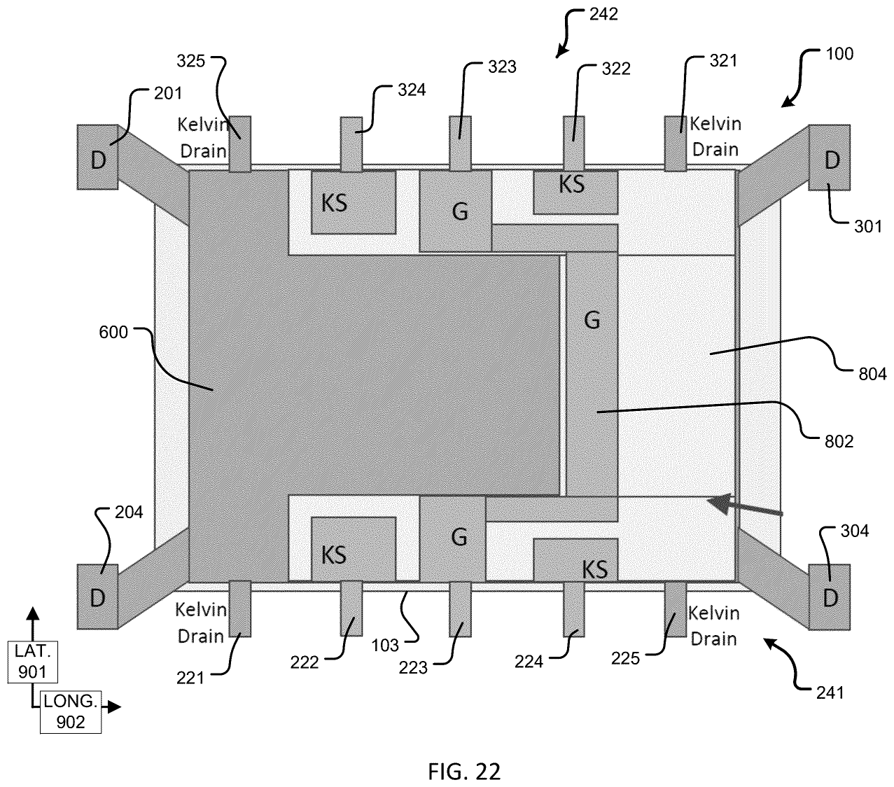

The reversible packages can also be connected in common-source configurations, common-source bidirectional configurations, common-drain switch configurations, common-drain bidirectional switch configurations, and/or the like. The common-source bidirectional configurations and the common-drain bidirectional switch configurations are shown in FIG. 21 and FIG. 22, respectively.

FIG. 17 illustrates a parallel connection of two reversible packages. This package configuration may be similar to the power package implementations illustrated in FIG. 5, FIG. 6, and FIG. 7. The same paralleling mechanism can be applied to power package implementations in any of the other figures.

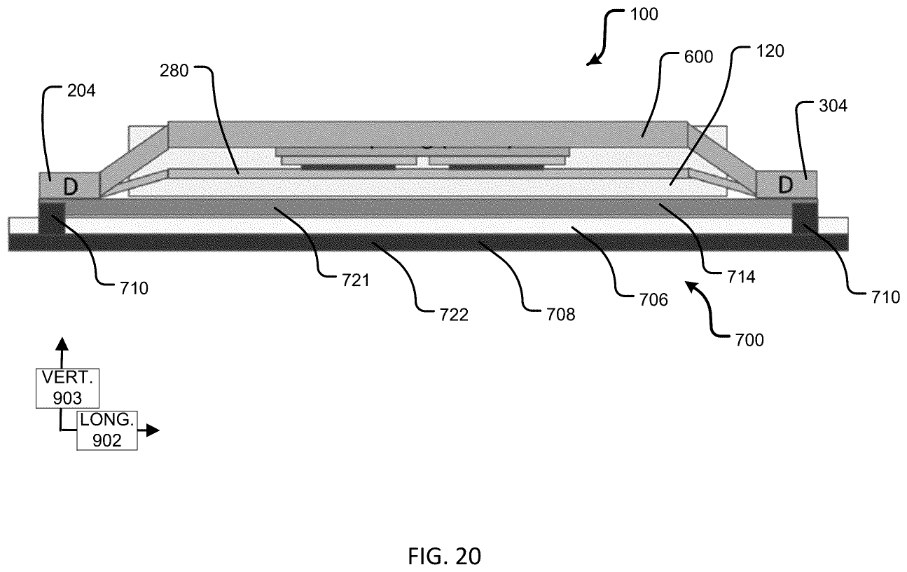

FIG. 18 illustrates a parallel connection of two reversible packages. This power package configuration may be similar to the power package illustrated in FIG. 5, FIG. 6, and FIG. 7. The same paralleling mechanism can be applied to the power package implementations in in any of the other figures. A PCB stackup is shown in FIG. 20, demonstrating multi-layer placement of rails to allow better utilization of top layer space for signal connections and clearances.

FIG. 19 illustrates a common-drain connection of two reversible packages. This power package configuration may be similar to the power package illustrated in FIG. 5, FIG. 6, and FIG. 7. The same paralleling mechanism can be applied to the power package implementations in any of the other figures.

FIG. 21 illustrates a common-source connection of two reversible packages. This power package configuration may be similar to the power package implementations illustrated in FIG. 5, FIG. 6, and FIG. 7. The same paralleling mechanism can be applied to the power package implementations in any of the other figures. Further details of the power package 100 as well as various configurations in implementations of the power package 100 are provided below.

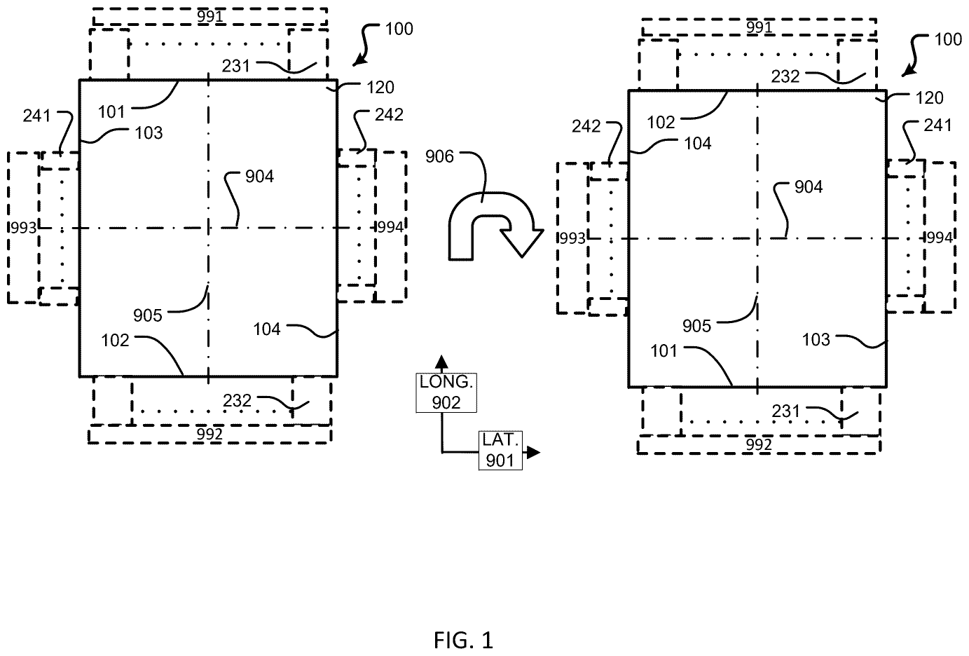

FIG. 1 illustrates top views of a power package according to aspects of the disclosure.

In particular, FIG. 1 illustrates top views of a power package 100 according to aspects of the disclosure prior to reversal of the power package 100 and after reversal of the power package 100. In aspects, the power package 100 may be implemented as a power package, a reversible power package, a reversible power package, a reversible discrete package, a symmetric package, a symmetric discrete package, and/or the like.

In aspects, the power package 100 may include an assembly 120, first power terminals 231, second power terminals 232, first signal terminals 241, second signal terminals 242, and/or the like.

The assembly 120 may include a first power package side 101 and a second power package side 102. The first power package side 101 and the second power package side 102 may be arranged on opposing sides of the assembly 120 and/or the power package 100. In aspects, the first power package side 101 and the second power package side 102 may be arranged parallel to a lateral axis 901 of the power package 100 as illustrated in FIG. 1.

The assembly 120 may include a third power package side 103 and a fourth power package side 104. The third power package side 103 and the fourth power package side 104 may be arranged on opposing sides of the assembly 120 and/or the power package 100. In aspects, the third power package side 103 and the fourth power package side 104 may be arranged parallel to a longitudinal axis 902 of the power package 100 and/or the assembly 120 as illustrated in FIG. 1.

In aspects, the first power terminals 231 may be arranged at the first power package side 101 of the power package 100; and the second power terminals 232 may be arranged at the second power package side 102 of the power package 100. Accordingly, the first power terminals 231 and the second power terminals 232 may be arranged on opposing sides of the power package 100. In aspects, the first power terminals 231 may extend generally along the longitudinal axis 902 from the first power package side 101. In aspects, the second power terminals 232 may extend generally along the longitudinal axis 902 from the second power package side 102.

Further, the first power terminals 231 may connect to respective first power connections 991 of an application (illustrated schematically), a circuit board, a system, and/or the like (hereinafter “application”); and the second power terminals 232 may connect to respective second power connections 992 of the application.

In aspects, the first signal terminals 241 may be arranged at the third power package side 103; and the second signal terminals 242 may be arranged at the fourth power package side 104. Accordingly, the first signal terminals 241 and the second signal terminals 242 may be arranged on opposing sides of the power package 100. In aspects, the first signal terminals 241 may extend generally along the lateral axis 901 from the third power package side 103. In aspects, the second signal terminals 242 may extend generally along the lateral axis 901 from the fourth power package side 104.

Further, the first signal terminals 241 may connect to respective first signal connections 993 to the application; and the second signal terminals 242 may connect to respective second signal connections 994 to the application.

In aspects as disclosed herein, the power package 100 may be configured to be repositioned or reoriented, such as by rotation about an axis perpendicular to the lateral axis 901 and the longitudinal axis 902. More specifically, the power package 100 may be configured to allow a physical positioning and/or orientation of the power package 100 to be reversed or reoriented and provide commensurate operation of the power package 100. For example, the power package 100 to be reversed or reoriented 180°. In other words, the power package 100 may be configured to provide a same operating capabilities, functionalities, and/or the like independent of an orientation of the power package 100.

In aspects, an arrangement and location of the first power terminals 231 on the first power package side 101 may be symmetrical with respect to an arrangement and location the second power terminals 232 on the second power package side 102.

In aspects, the power package 100 may have a lateral axis of symmetry 904. In aspects, an arrangement and location of the first power terminals 231 may be symmetrical about the lateral axis of symmetry 904 with respect to an arrangement and location the second power terminals 232.

In aspects, an arrangement and location of the first signal terminals 241 on the third power package side 103 may be symmetrical with respect to an arrangement and location the second signal terminals 242 on the fourth power package side 104.

In aspects, the power package 100 may have a longitudinal axis of symmetry 905. In aspects, an arrangement and location of the first signal terminals 241 may be symmetrical about the longitudinal axis of symmetry 905 with respect to an arrangement and location the second signal terminals 242.

In aspects, an arrangement and location of the first power terminals 231 on the first power package side 101 may be symmetrical with respect to one side of the first power package side 101 and another side of the first power package side 101. In aspects, an arrangement and location the second power terminals 232 on the second power package side 102 may be symmetrical with respect to one side of the second power package side 102 and another side of the second power package side 102.

In aspects, an arrangement and location of the first signal terminals 241 on the third power package side 103 may be symmetrical with respect to one side of the third power package side 103 and another side of the third power package side 103. In aspects, an arrangement and location the second signal terminals 242 on the fourth power package side 104 may be symmetrical with respect to one side of the fourth power package side 104 and another side of the fourth power package side 104.

In aspects, an arrangement and location of the first signal terminals 241 may be symmetrical about the lateral axis of symmetry 904 with respect to an arrangement and location the second signal terminals 242.

As illustrated in FIG. 1, a positioning of the power package 100 is illustrated with an initial orientation on a left side of FIG. 1. Thereafter, the power package 100 may be reversed or reoriented 180° as illustrated on a right side of FIG. 1. In particular, arrow 906 illustrates an exemplary movement or reorientation of the power package 100 illustrated on the left side of FIG. 1 to right side of FIG. 1, which results in a reorientation of the power package 100.

In aspects, after reorienting the power package 100, locations of the first power terminals 231 and the second power terminals 232 may be reversed. In particular, the first power terminals 231 may now connect to the respective second power connections 992; and the second power terminals 232 may now connect to the respective first power connections 991.

In this regard, the power package 100 may be configured to operate in a manner when the first power terminals 231 connect to the respective first power connections 991 and the second power terminals 232 connect to the respective second power connections 992 of the application components as implemented by the power package 100 illustrated on the left side of FIG. 1.

Further, the power package 100 may be configured to operate in a same manner when the first power terminals 231 connect to the respective second power connections 992 and the second power terminals 232 connect to the respective first power connections 991 as implemented by the power package 100 illustrated on the right side of FIG. 1.

In aspects, after reorienting the power package 100, locations of the first signal terminals 241 and the second signal terminals 242 may be reversed. In particular, the first signal terminals 241 may now connect to the respective second signal connections 994; and the second signal terminals 242 may now connect to the respective first signal connections 993 as implemented by the power package 100 illustrated on the right side of FIG. 1.

In this regard, the power package 100 may be configured to operate in a manner when the first signal terminals 241 connect to the respective first signal connections 993 and the second signal terminals 242 connect to the respective second signal connections 994 of the application components as illustrated by the power package 100 illustrated on the left side of FIG. 1.

Further, the power package 100 may be configured to operate in a same manner when the first signal terminals 241 connect to the respective second signal connections 994 and the second signal terminals 242 connect to the respective first signal connections 993 as implemented by the power package 100 illustrated on the right side of FIG. 1.

In aspects, the first signal terminals 241 and/or the second signal terminals 242 may include one or more implementations that include one or more Kelvin source terminals, Kelvin drain terminals, gate terminals, sensor terminals, and/or the like. In aspects, the first signal terminals 241 and/or the second signal terminals 242 may be implemented as sensor terminals. In this regard, the first signal terminals 241 and/or the second signal terminals 242 may connect to one or more temperature sensors, current sensors, strain sensors, and/or the like implemented within the power package 100.

As further illustrated in FIG. 1, the first signal terminals 241 may be arranged on the third power package side 103 between implementations of the first power terminals 231 and the second power terminals 232. As further illustrated in FIG. 1, the second signal terminals 242 may be arranged on the fourth power package side 104 between implementations of the first power terminals 231 and the second power terminals 232.

As further illustrated in FIG. 1, the first power terminals 231 may be arranged on the first power package side 101 between implementations of the first signal terminals 241 and the second signal terminals 242. As further illustrated in FIG. 1, the second power terminals 232 may be arranged on the second power package side 102 between implementations of the first signal terminals 241 and the second signal terminals 242.

The disclosure and figures make reference to certain axes that include the lateral axis 901, the longitudinal axis 902, and the vertical axis 903. In aspects, these axes are meant to describe the structural arrangement, spatial arrangement, and/or the like of various components of the power package 100 and/or features of various components of the power package 100. In aspects, the lateral axis 901 extends along a direction perpendicular to the longitudinal axis 902 and the vertical axis 903; the longitudinal axis 902 extends along a direction perpendicular to the lateral axis 901 and the vertical axis 903; and the vertical axis 903 extends along a direction perpendicular to the lateral axis 901 and the longitudinal axis 902. In aspects, utilization of the lateral axis 901 and the longitudinal axis 902 are not meant to denote that one axis of the power package 100 is longer or shorter than another axis of the power package 100. In aspects, a square implementation of the power package 100 may implement features with respect to the lateral axis 901 and the longitudinal axis 902 as described herein.

Aspects of the power package 100 illustrated in FIG. 1 may optionally include any other features of the power package 100 as described and illustrated herein. Further, aspects of the power package 100 illustrated in FIG. 1 and described therewith may optionally be implemented in any other implementations of the power package 100 as described and illustrated herein.

FIG. 2 illustrates a bottom view of an exemplary power package according to aspects of the disclosure.

FIG. 3 illustrates an upside down side view of the exemplary power package according to FIG. 2.

FIG. 4 illustrates a top view of an exemplary power die that may be implemented in the power package of FIG. 2.

FIG. 2 illustrates the power package 100 without the first signal terminals 241 and the second signal terminals 242 for ease of illustration and understanding. FIG. 2 further illustrates exemplary implementations of the assembly 120, the first power terminals 231, the second power terminals 232, and/or the like. Further, the power package 100 may include a top substrate 600, at least one power die 111, at least one source bar 280, and/or the like.

In aspects, the power package 100 may implement a single power die. In aspects, the power package 100 may implement a single implementation of the at least one power die 111. In aspects, the power package 100 may be configured as a power discrete package implementing the single at least one power die 111.

In aspects, the power package 100 may implement two power dies. In aspects, the power package 100 may implement two implementations of the at least one power die 111. In aspects, the power package 100 may be configured as a power discrete package implementing two implementations of the at least one power die 111.

In aspects, the power package 100 may implement the first power terminals 231 as a first power terminal 201, a second power terminal 202, a third power terminal 203, and a fourth power terminal 204.

In aspects, the power package 100 may implement the second power terminals 232 as a first power terminal 301, a second power terminal 302, a third power terminal 303, and a fourth power terminal 304.

In particular, the first power terminal 201, the second power terminal 202, the third power terminal 203, and the fourth power terminal 204 may be arranged at a first power package side 101 of the power package 100; and the first power terminal 301, the second power terminal 302, the third power terminal 303, and the fourth power terminal 304 may be arranged at a second power package side 102 of the power package 100.

With reference to FIG. 3 and FIG. 4, the power package 100 may include risers 188 arranged on the at least one power die 111. In aspects, the risers 188 may be an electrically conductive material and/or an electrically conductive structure arranged on the at least one power die 111. In aspects, the risers 188 may be attached to the at least one power die 111 by an adhesive, soldering, sintering, eutectic bonding, thermal compression bonding, ultrasonic bonding/welding, and/or the like as described herein.

With reference to FIG. 4, the at least one power die 111 may include at least one source pad 191, at least one gate pad 193, and at least one Kelvin source pad 195. Further, the at least one power die 111 may include a passivation layer on an upper surface adjacent the at least one source pad 191, the at least one gate pad 193, the at least one Kelvin source pad 195, and/or the like.

In aspects, the risers 188 may be on the at least one source pad 191, electrically connected to the at least one source pad 191, attached to the at least one source pad 191, and/or the like. In aspects, the risers 188 may be attached to the at least one source pad 191 by an adhesive, soldering, sintering, eutectic bonding, thermal compression bonding, ultrasonic bonding/welding, and/or the like as described herein.

FIG. 3 illustrates a stack-up inside the power package 100, where the power package 100 is flipped with a top side of the power package 100 facing down and a bottom side of the power package 100 facing up. In this regard, the power package 100 may be implemented as a flipped power package. However, in other aspects, the power package 100 may not be implemented as a flipped power package.

In aspects, the top substrate 600 may be a metal plate. In aspects, the top substrate 600 may be configured as a top slug. In aspects, the first power terminal 201, the fourth power terminal 204, the first power terminal 301, and the fourth power terminal 304 may be connected directly, connected indirectly, attached, and/or the like to the top substrate 600. In aspects, the first power terminal 201, the fourth power terminal 204, the first power terminal 301, and the fourth power terminal 304 may be attached to the top substrate 600 with an adhesive, soldering, sintering, eutectic bonding, thermal compression bonding, ultrasonic bonding/welding, and/or the like as described herein. In aspects, the first power terminal 201, the fourth power terminal 204, the first power terminal 301, and the fourth power terminal 304 may form part of the top substrate 600.

In aspects, the first power terminal 201, the fourth power terminal 204, the first power terminal 301, and the fourth power terminal 304 may form drain legs and/or thick drain legs sticking out towards the bottom side of the power package 100 and/or the top substrate 600. In aspects, In particular, the first power terminal 201, the fourth power terminal 204, the first power terminal 301, and the fourth power terminal 304 may extend generally below the top substrate 600 along a vertical axis 903.

In aspects, one or more of the first power terminal 201, the fourth power terminal 204, the first power terminal 301, and the fourth power terminal 304 may include a foot portion configured to electrically connect to the application. In aspects, the first power terminal 201, the fourth power terminal 204, the first power terminal 301, and the fourth power terminal 304 may connect through the foot portion to the respective first power connections 991 or the respective second power connections 992. In other aspects, the power package 100 may be implemented without the fourth power terminal 204 and the fourth power terminal 304 and make connection to the application through a bottom surface of the top substrate 600 (not shown). In aspects, the connection may an adhesive, soldering, sintering, eutectic bonding, thermal compression bonding, ultrasonic bonding/welding, and/or the like as described herein.

In aspects, the at least one power die 111 may implement a drain contact on a bottom of the at least one power die 111. In aspects, the drain contact of the at least one power die 111 may be connected directly, connected indirectly, attached, and/or the like to the top substrate 600. In aspects, the at least one power die 111 may be attached to the top substrate 600 by an adhesive, soldering, sintering, eutectic bonding, thermal compression bonding, ultrasonic bonding/welding, other die attach mechanisms, and/or the like as described herein.

In aspects, the at least one source pad 191 may be arranged on a surface of the at least one power die 111. In aspects, the at least one source pad 191 of the at least one power die 111 may be provided with the risers 188. In aspects, the risers 188 may be attached to the at least one source bar 280. In aspects, the at least one source bar 280 may be implemented as a metal bar, a thick metal bar, and/or the like that may be attached the risers 188, the at least one source pad 191, and/or the at least one power die 111.

In aspects, the second power terminal 202, the third power terminal 203, the second power terminal 302, and the third power terminal 303 may form source legs, thick source legs, and/or the like sticking out towards the bottom side of the power package 100 and/or the at least one source bar 280. In particular, the second power terminal 202, the third power terminal 203, the second power terminal 302, and the third power terminal 303 may extend generally below the at least one source bar 280 along a vertical axis 903.

In aspects, the at least one source bar 280 may have pinouts implemented by the second power terminal 202, the third power terminal 203, the second power terminal 302, and the third power terminal 303 that may be pointed towards the bottom side of the power package 100. In aspects, one or more of the second power terminal 202, the third power terminal 203, the second power terminal 302, and the third power terminal 303 may include a foot portion configured to electrically connect to the application. In aspects, the second power terminal 202, the third power terminal 203, the second power terminal 302, and the third power terminal 303 may connect through the foot portion to the respective first power connections 991 or the respective second power connections 992. In aspects, the connection may an adhesive, soldering, sintering, eutectic bonding, thermal compression bonding, ultrasonic bonding/welding, and/or the like as described herein.

In aspects, the power package 100 may be implemented as an assembly that includes the assembly 120; and the assembly 120 and/or the power package 100 may include and/or may be encapsulated in epoxy, overmolded, overmolded with epoxy, potted, potted with a dielectric material, such as dielectric isolation gels such as Silica.

In aspects, the at least one power die 111 may include a drain pad that may be arranged on the top substrate 600. Moreover, the drain pad may be electrically connected to the top substrate 600. Further, the top substrate 600 may be electrically connected to the first power terminal 201, the first power terminal 301, the fourth power terminal 204, and the fourth power terminal 304 through the top substrate 600.

With reference to FIG. 3 and FIG. 4, the risers 188 may be electrically connected to the at least one source pad 191. Further, the risers 188 may be electrically connected to the at least one source bar 280.

In aspects, the top substrate 600 may be configured with the first power terminal 201, the fourth power terminal 204, the first power terminal 301, the fourth power terminal 304, and/or the like extending out towards a bottom side the power package 100. In aspects, the first power terminal 201, the fourth power terminal 204, the first power terminal 301, the fourth power terminal 304, and/or the like may be configured as drain legs, thick drain legs, and/or the like sticking out towards a bottom side the power package 100.

It should be noted that the power package 100 is illustrated implementing four power terminals on the first power package side 101 of the power package 100 and four power terminals on the second power package side 102 of the power package 100. However, in other aspects of the power package 100, there may be two, three, four, five, six, seven, or eight implementations of the first power terminals 231 on the first power package side 101 of the power package 100 and two, three, four, five, six, seven, or eight implementations of the second power terminals 232 on the second power package side 102 of the power package 100.

Aspects of the power package 100 illustrated in FIG. 2 and FIG. 3 may optionally include any other features of the power package 100 as described and illustrated herein. Further, aspects of the power package 100 illustrated in FIG. 2 and FIG. 3 and described therewith may optionally be implemented in any other implementations of the power package 100 as described and illustrated herein. Aspects of the at least one power die 111 illustrated in FIG. 4 may optionally include any other features of the at least one power die 111 as described and illustrated herein. Further, aspects of the at least one power die 111 illustrated in FIG. 4 and described therewith may optionally be implemented in any other implementations of the at least one power die 111 as described and illustrated herein.

FIG. 5 illustrates a bottom view of an exemplary power package according to aspects of the disclosure.

FIG. 6 illustrates an upside down side view of the exemplary power package according to FIG. 5; and FIG. 6 also illustrates an upside up side view of the exemplary power package according to FIG. 5.

FIG. 7 illustrates an upside up side view of the exemplary power package according to FIG. 5 arranged on an application.

In particular, a more detailed internal view of the power package 100 is shown in FIG. 5, FIG. 6, and FIG. 7. A cross-section of the power package 100 when surface mounted on an application interface structure 700, such as a printed circuit board (PCB), is shown in FIG. 7.

The bottom view of interiors of the power package 100 with power and signal connections is shown in FIG. 5. The power package 100 may implement two parallel implementations of the at least one power die 111 that may enable a full utilization of all signal pins in this implementation of the power package 100.

In aspects, the power package 100 may implement the first signal terminals 241 as a first signal terminal 221, a second signal terminal 222, a third signal terminal 223, a fourth signal terminal 224, a fifth signal terminal 225, and/or the like.

In aspects, the first signal terminals 241 may be implemented as one or more Kelvin source terminals, Kelvin drain terminals, gate terminals, sensor terminals, and/or the like. In aspects, the first signal terminals 241 may connect to the at least one power die 111 by at least one interconnect 704.

The at least one interconnect 704 may be one or more wires, wire bonds, ribbons, clips, and/or the like. In aspects, the at least one interconnect 704 may connect to the at least one power die 111 and include an adhesive, soldering, sintering, eutectic bonding, thermal compression bonding, ultrasonic bonding/welding, and/or the like as described herein. In aspects, the at least one interconnect 704 may connect to the first signal terminals 241 and include an adhesive, soldering, sintering, eutectic bonding, thermal compression bonding, ultrasonic bonding/welding, and/or the like as described herein.

In aspects, the first signal terminal 221, the second signal terminal 222, the third signal terminal 223, and the fifth signal terminal 225 may be one or more Kelvin source terminals that may connect via the at least one interconnect 704 to the at least one Kelvin source pad 195 and/or the at least one source pad 191 of the at least one power die 111. In aspects, the fourth signal terminal 224 may be a gate terminal that may connect via the at least one interconnect 704 to the at least one gate pad 193 of the at least one power die 111.

In aspects, the power package 100 may implement the second signal terminals 242 as a first signal terminal 321, a second signal terminal 322, a third signal terminal 323, a fourth signal terminal 324, a fifth signal terminal 325, and/or the like.

In aspects, the second signal terminals 242 may be implemented as one or more Kelvin source terminals, Kelvin drain terminals, gate terminals, sensor terminals, and/or the like. In aspects, the second signal terminals 242 may connect to the at least one power die 111 by at least one interconnect 704.

In aspects, the first signal terminal 321, the second signal terminal 322, the third signal terminal 323, and the fifth signal terminal 325 may be one or more Kelvin source terminals that may connect via the at least one interconnect 704 to the at least one Kelvin source pad 195 and/or the at least one source pad 191 of the at least one power die 111. In aspects, the fourth signal terminal 324 may be a gate terminal that may connect via the at least one interconnect 704 to the at least one gate pad 193 of the at least one power die 111.

In particular, the first signal terminal 221, the second signal terminal 222, and the third signal terminal 223, the fourth signal terminal 224, and the fifth signal terminal 225 may be arranged at the third power package side 103 of the power package 100; and the first signal terminal 321, the second signal terminal 322, the third signal terminal 323, the fourth signal terminal 324, and the fifth signal terminal 325 may be arranged at the fourth power package side 104. Further, the first signal terminal 221, the second signal terminal 222, and the third signal terminal 223, the fourth signal terminal 224, and the fifth signal terminal 225 may connect to respective first signal connections 993 of the application (not shown); and the first signal terminal 321, the second signal terminal 322, the third signal terminal 323, the fourth signal terminal 324, and the fifth signal terminal 325 may connect to respective second signal connections 994 of the application components (not shown).

In aspects, the first signal terminal 321 may be a Kelvin source terminal, the second signal terminal 322 may be a Kelvin source terminal, the third signal terminal 323 may be a Kelvin source terminal, the fourth signal terminal 324 may be a gate terminal, and the fifth signal terminal 325 may be a Kelvin source terminal.

In aspects, the first signal terminal 221 may be a Kelvin source terminal, the second signal terminal 222 may be a Kelvin source terminal, the third signal terminal 223 may be a Kelvin source terminal, the fourth signal terminal 224 may be a gate terminal, and the fifth signal terminal 225 may be a Kelvin source terminal.

FIG. 6 illustrates the power package 100 arranged with the upside down (upper image of the power package 100); and FIG. 6 also illustrates the power package 100 arranged with the upside down up (lower image of the power package 100). In this regard, the power package 100 may be implemented as a flipped power package. However, in other aspects, the power package 100 may not be implemented as a flipped power package.

FIG. 7 illustrates the power package 100 may be arranged on the application interface structure 700. In particular, the application interface structure 700 may be a printed circuit board (PCB), a substrate, a circuit board, a printed wiring board (PWB), a medium used to connect electronic components to one another in a controlled manner, and/or the like. In aspects, the application interface structure 700 may be implemented as a laminated sandwich structure of one or more conductive and insulating layers. In aspects, the application interface structure 700 may include one or more conductive layers, traces, planes and/or the like. In aspects, the application interface structure 700 may be etched from one or more sheet layers of copper laminated onto and/or between sheet layers of a non-conductive substrate.

Aspects of the power package 100 illustrated in FIGS. 5-7 may optionally include any other features of the power package 100 as described and illustrated herein. Further, aspects of the power package 100 illustrated in FIGS. 5-7 and described therewith may optionally be implemented in any other implementations of the power package 100 as described and illustrated herein.

FIG. 8 is a top view of another exemplary power die that may be implemented in the power package according to aspects of the disclosure.

FIG. 9 is a top view of another exemplary power die that may be implemented in the power package according to aspects of the disclosure.

FIG. 10 is a top view of another exemplary power die that may be implemented in the power package according to aspects of the disclosure.

In particular, some of the at least one power die 111 that may be compatible with the power package 100 are shown in FIG. 8, FIG. 9, and FIG. 10. With reference to FIG. 8, FIG. 9, and FIG. 10, the at least one power die 111 may include the at least one source pad 191, the at least one gate pad 193, and the at least one Kelvin source pad 195. Further, the at least one power die 111 may include the passivation layer on an upper surface adjacent the at least one source pad 191, the at least one gate pad 193, the at least one Kelvin source pad 195, and/or the like.

Additionally, FIG. 8 illustrates an implementation of the at least one power die 111 having two implementations of the at least one Kelvin source pad 195 and two implementations of the at least one source pad 191.

Further, FIG. 9 illustrates an implementation of the at least one power die 111 having a single implementation of the at least one Kelvin source pad 195 and two implementations of the at least one source pad 191.

Additionally, FIG. 10 illustrates an implementation of the at least one power die 111 having a single implementation of the at least one Kelvin source pad 195 and two implementations of the at least one source pad 191 with the at least one Kelvin source pad 195 and the at least one gate pad 193 reversed in comparison to FIG. 9.

Aspects of the at least one power die 111 illustrated in FIGS. 8-10 may optionally include any other features of the at least one power die 111 as described and illustrated herein. Further, aspects of the at least one power die 111 illustrated in FIGS. 8-10 and described therewith may optionally be implemented in any other implementations of the at least one power die 111 as described and illustrated herein.

FIG. 11 illustrates a bottom view of an exemplary power package according to aspects of the disclosure.

In particular, FIG. 11 illustrates the power package 100 that may include the first power terminal 301, the second power terminal 302, the third power terminal 303, the fourth power terminal 304, the at least one power die 111, the first power terminal 201, the second power terminal 202, the third power terminal 203, the fourth power terminal 204, the at least one source bar 280, and/or the like. Further, the power package 100 illustrated in FIG. 11 may include the first signal terminal 321, the second signal terminal 322, the third signal terminal 323, the fourth signal terminal 324, and the fifth signal terminal 325. Additionally, the power package 100 illustrated in FIG. 11 may include the first signal terminal 221, the second signal terminal 222, the third signal terminal 223, the fourth signal terminal 224, and the fifth signal terminal 225. Further, the power package 100 may include the at least one interconnect 704, which are illustrated and not otherwise denoted.

In aspects, the first signal terminal 321 may be a Kelvin source terminal, the third signal terminal 323 may be a Kelvin source terminal, the fifth signal terminal 325 may be a Kelvin source terminal, the fourth signal terminal 324 may be a gate terminal, and the fifth signal terminal 325 may be a Kelvin source terminal.

In aspects, the first signal terminal 221 may be a Kelvin source terminal, the third signal terminal 223 may be a Kelvin source terminal, the third signal terminal 223 may be a Kelvin source terminal, the second signal terminal 222 and the fourth signal terminal 224 may be a gate terminal, and the fifth signal terminal 225 may be a Kelvin source terminal.

Aspects of the power package 100 illustrated in FIG. 11 may optionally include any other features of the power package 100 as described and illustrated herein. Further, aspects of the power package 100 illustrated in FIG. 11 and described therewith may optionally be implemented in any other implementations of the power package 100 as described and illustrated herein.

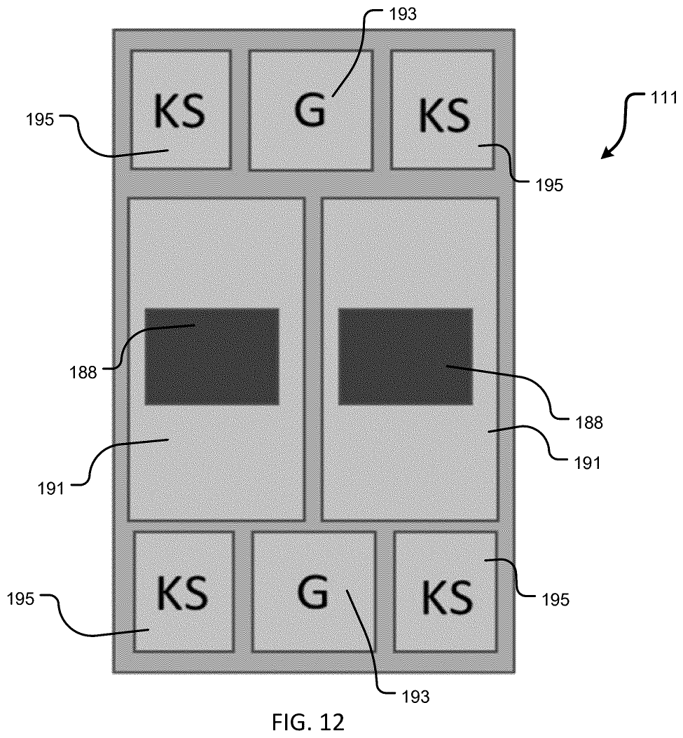

FIG. 12 is a top view of another exemplary power die that may be implemented in the power package according to aspects of the disclosure.

With reference to FIG. 12, the at least one power die 111 may include the at least one source pad 191, the at least one gate pad 193, and the at least one Kelvin source pad 195. Further, the at least one power die 111 may include the passivation layer on an upper surface adjacent the at least one source pad 191, the at least one gate pad 193, the at least one Kelvin source pad 195, and/or the like.

Further, FIG. 12 illustrates an implementation of the at least one power die 111 having four implementations of the at least one Kelvin source pad 195 and two implementations of the at least one gate pad 193.

Aspects of the at least one power die 111 illustrated in FIG. 12 may optionally include any other features of the at least one power die 111 as described and illustrated herein. Further, aspects of the at least one power die 111 illustrated in FIG. 12 and described therewith may optionally be implemented in any other implementations of the at least one power die 111 as described and illustrated herein.

FIG. 13 illustrates a bottom view of an exemplary power package according to aspects of the disclosure.

FIG. 14 illustrates a top view of the power package according to FIG. 13.

In particular, FIG. 13 illustrates the power package 100 that may include the first power terminal 301, the second power terminal 302, the third power terminal 303, the fourth power terminal 304, the at least one power die 111, the first power terminal 201, the second power terminal 202, the third power terminal 203, the fourth power terminal 204, the at least one source bar 280, and/or the like. Further, the power package 100 illustrated in FIG. 13 may include the first signal terminal 321, the second signal terminal 322, the third signal terminal 323, the fourth signal terminal 324, and the fifth signal terminal 325. Additionally, the power package 100 illustrated in FIG. 13 may include the first signal terminal 221, the second signal terminal 222, the third signal terminal 223, the fourth signal terminal 224, and the fifth signal terminal 225. Further, the power package 100 may include the at least one interconnect 704, which are illustrated and not otherwise denoted.

Additionally, the power package 100 illustrated in FIG. 13 may include a sixth signal terminal 226 and a sixth signal terminal 326.

In aspects, the first signal terminal 321 may be a Kelvin source terminal, the second signal terminal 322 may be a Kelvin source terminal, the third signal terminal 323 may be a Kelvin source terminal, the fourth signal terminal 324 may be a gate terminal, the fifth signal terminal 325 may be a Kelvin source terminal, and the sixth signal terminal 326 may be a Kelvin drain terminal.

In aspects, the first signal terminal 221 may be a Kelvin source terminal, the second signal terminal 222 may be a Kelvin source terminal, the third signal terminal 223 may be a Kelvin source terminal, the fourth signal terminal 224 may be a gate terminal, the fifth signal terminal 225 may be a Kelvin source terminal, and the sixth signal terminal 226 may be a Kelvin drain terminal.

Aspects of the power package 100 illustrated in FIGS. 13 and 14 may optionally include any other features of the power package 100 as described and illustrated herein. Further, aspects of the power package 100 illustrated in FIGS. 13 and 14 and described therewith may optionally be implemented in any other implementations of the power package 100 as described and illustrated herein.

FIG. 15 illustrates a bottom view of an exemplary power package according to aspects of the disclosure.

FIG. 16 illustrates a top view of the power package according to FIG. 15.

In particular, FIG. 15 illustrates the power package 100 that may include the first power terminal 301, the second power terminal 302, the third power terminal 303, the fourth power terminal 304, the at least one power die 111, the first power terminal 201, the second power terminal 202, the third power terminal 203, the fourth power terminal 204, the at least one source bar 280, and/or the like. Further, the power package 100 illustrated in FIG. 15 may include the first signal terminal 321, the second signal terminal 322, the third signal terminal 323, the fourth signal terminal 324, and the fifth signal terminal 325. Additionally, the power package 100 illustrated in FIG. 15 may include the first signal terminal 221, the second signal terminal 222, the third signal terminal 223, the fourth signal terminal 224, and the fifth signal terminal 225. Further, the power package 100 may include the at least one interconnect 704, which are illustrated and not otherwise denoted.

Additionally, the power package 100 illustrated in FIG. 15 may include a sixth signal terminal 226 and a sixth signal terminal 326. Further, the power package 100 illustrated in FIG. 15 may include a seventh signal terminal 227 and a seventh signal terminal 327.

In aspects, the second signal terminal 322, the fourth signal terminal 324, and the sixth signal terminal 326 may be Kelvin source terminals, the third signal terminal 323 and the fifth signal terminal 325 may be gate terminals, and the first signal terminal 321 and the seventh signal terminal 327 may be a Kelvin drain terminal.

In aspects, the second signal terminal 222, the fourth signal terminal 224, and the sixth signal terminal 226 may be Kelvin source terminals, the third signal terminal 223 and the fifth signal terminal 225 may be gate terminals, and the first signal terminal 221 and the seventh signal terminal 227 may be a Kelvin drain terminal.

Aspects of the power package 100 illustrated in FIGS. 15 and 16 may optionally include any other features of the power package 100 as described and illustrated herein. Further, aspects of the power package 100 illustrated in FIGS. 15 and 16 and described therewith may optionally be implemented in any other implementations of the power package 100 as described and illustrated herein.

FIG. 17 illustrates a parallel connection of two implementations of the power package according to the aspects of the disclosure.

In particular, FIG. 17 illustrates a parallel connection of two implementations of the power package 100 according to aspects of the disclosure. Although FIG. 17 illustrates a particular implementation of the power package 100, optionally any implementation of the power package 100 disclosed herein may be implemented.

In aspects, respective implementations of the first power terminals 231 and the second power terminals 232 may be arranged on the application interface structure 700. In aspects, respective implementations of the first power terminals 231 and the second power terminals 232 may be arranged on power rails of the application interface structure 700.

In aspects, the application interface structure 700 may include first power rails 721 and second power rails 722. In aspects, implementations of the first power terminals 231 and the second power terminals 232 may be arranged on the first power rails 721; and other implementations of the first power terminals 231 and the second power terminals 232 may be arranged on the second power rails 722.

In aspects, source implementations of the first power terminals 231 and the second power terminals 232 may be arranged on the second power rails 722 of the application interface structure 700. In aspects, drain implementations of the first power terminals 231 and the second power terminals 232 may be arranged on the first power rails 721 of the application interface structure 700.

In aspects, the first power rails 721 may connect to drain terminal implementations of the first power terminals 231 and the second power terminals 232; and the second power rails 722 may connect to source terminal implementations of the first power terminals 231 and the second power terminals 232. In aspects as illustrated, there may be two implementations of the first power rails 721 along sides of the implementations of the power package 100; and there may be a single implementation of the second power rails 722 centrally arranged with the implementations of the power package 100.

Additionally, gate drive signals may be provided by gate drivers 702. In aspects, the gate drivers 702 may be arranged on or adjacent to the application interface structure 700. In aspects, the gate drive signals may be provided by the gate drivers 702 that may be arranged and connected from a perpendicular direction to the power package 100. In aspects, the gate drive signals may be provided by the gate drivers 702 that may be arranged and connected from a perpendicular direction to the longitudinal axis 902 of the power package 100. In aspects, the gate drive signals may be provided by the gate drivers 702 that may be arranged and connected from a direction parallel to the lateral axis 901 of the power package 100.

Aspects of the application interface structure 700 illustrated in FIG. 17 may optionally include any other features of the application interface structure 700 as described and illustrated herein. Further, aspects of the application interface structure 700 illustrated in FIG. 17 and described therewith may optionally be implemented in any other implementations of the application interface structure 700 as described and illustrated herein.

FIG. 18 illustrates a parallel connection of two implementations of the power package according to the aspects of the disclosure.

In particular, FIG. 18 illustrates a configuration of two implementations of the power package 100 according to aspects of the disclosure. Although FIG. 18 illustrates a particular implementation of the power package 100, optionally any implementation of the power package 100 disclosed herein may be implemented.

Additionally, the configuration of FIG. 18 may include the first power terminals 231 and the second power terminals 232 arranged on the first power rails 721 and the second power rails 722 of the application interface structure 700 as previously described. Further, the configuration of FIG. 18 may include the gate drivers 702 as previously described.

Additionally, one of the first power rails 721 and the second power rails 722 the first power rails 721 may be on an inner layer of the application interface structure 700 to reduce inductance and allow the top layer space of the application interface structure 700 to be better utilized. For example, the first power rails 721, which may be implemented as drain rails, may be on an inner layer of the application interface structure 700 to reduce inductance and allow the top layer space of the application interface structure 700 to be better utilized.

Aspects of the application interface structure 700 illustrated in FIG. 18 may optionally include any other features of the application interface structure 700 as described and illustrated herein. Further, aspects of the application interface structure 700 illustrated in FIG. 18 and described therewith may optionally be implemented in any other implementations of the application interface structure 700 as described and illustrated herein.

FIG. 19 illustrates a common-drain connection of two implementations of the power package according to the aspects of the disclosure.

FIG. 20 is a cross-sectional view of the parallel connection of FIG. 19.

In particular, FIG. 19 illustrates a common-drain connection of two implementations of the power package 100 according to aspects of the disclosure. More specifically, FIG. 19 illustrates a common-drain connection of two implementations of the power package 100. Although FIG. 19 illustrates a particular implementation of the power package 100, optionally any implementation of the power package 100 disclosed herein may be implemented.

Additionally, the configuration of FIG. 18 may include the first power terminals 231 and the second power terminals 232 arranged on the first power rails 721 and the second power rails 722 of the application interface structure 700 as previously described. Further, the configuration of FIG. 18 may include the gate drivers 702 as previously described.

FIG. 20 illustrates exemplary implementations of the application interface structure 700 having an implementation of the power package 100 arranged thereon. In particular, the application interface structure 700 may include a top layer 714, and inter-layer dielectric layer 706, and an inner layer 708. Additionally, the application interface structure 700 may include through hole connections 710 for connecting the inner layer 708 to the fourth power terminal 204 of the power package 100 and the fourth power terminal 304 of the power package 100.

In aspects, the top layer 714 may be configured to implement at least in part the second power rails 722. In aspects, the inner layer 708 may be configured to implement at least in part the first power rails 721. In aspects, the hole connections 710 may connect the inner layer 708 to the first power rails 721.

Aspects of the application interface structure 700 illustrated in FIGS. 19 and 20 may optionally include any other features of the application interface structure 700 as described and illustrated herein. Further, aspects of the application interface structure 700 illustrated in FIGS. 19 and 20 and described therewith may optionally be implemented in any other implementations of the application interface structure 700 as described and illustrated herein.

FIG. 21 illustrates a parallel common-source bidirectional configuration of two implementations of the power package according to the aspects of the disclosure.

In particular, FIG. 21 illustrates a configuration of two implementations of the power package 100 according to aspects of the disclosure. More specifically, FIG. 21 illustrates a common-source connection of two implementations of the power package 100. Although FIG. 21 illustrates a particular implementation of the power package 100, optionally any implementation of the power package 100 disclosed herein may be implemented.

Additionally, the configuration of FIG. 21 may include the first power terminals 231 and the second power terminals 232 arranged on the first power rails 721 and the second power rails 722 of the application interface structure 700 as previously described. Further, the configuration of FIG. 18 may include the gate drivers 702 as previously described.

Aspects of the application interface structure 700 illustrated in FIG. 21 may optionally include any other features of the application interface structure 700 as described and illustrated herein. Further, aspects of the application interface structure 700 illustrated in FIG. 21 and described therewith may optionally be implemented in any other implementations of the application interface structure 700 as described and illustrated herein.

FIG. 22 illustrates a bottom view of an exemplary power package according to aspects of the disclosure.

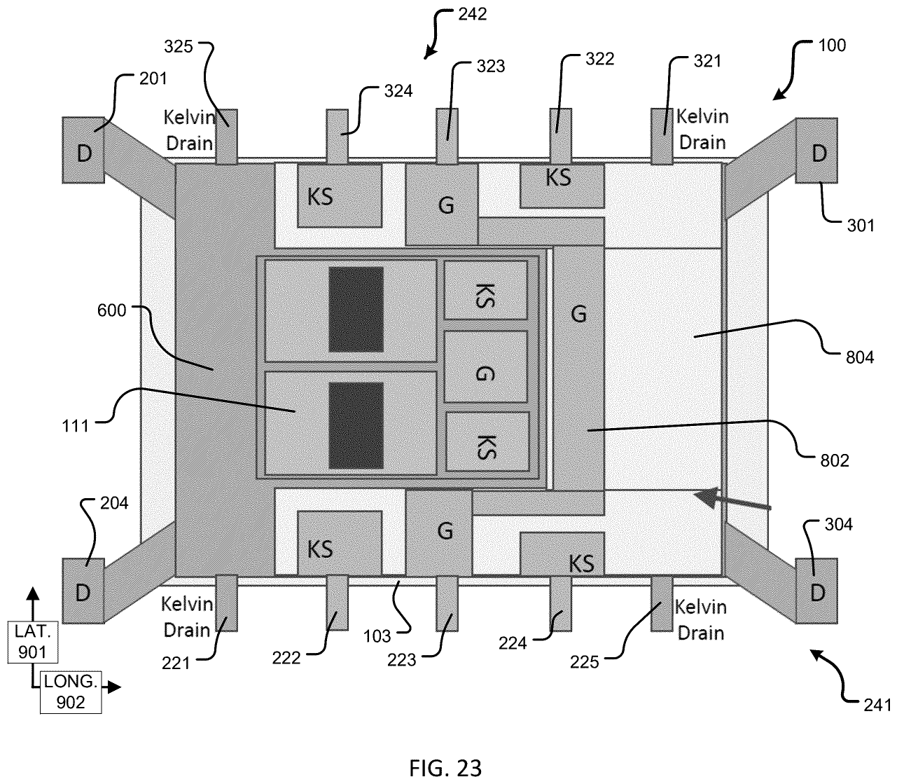

FIG. 23 illustrates a further more detailed bottom view of the exemplary power package according to FIG. 22.

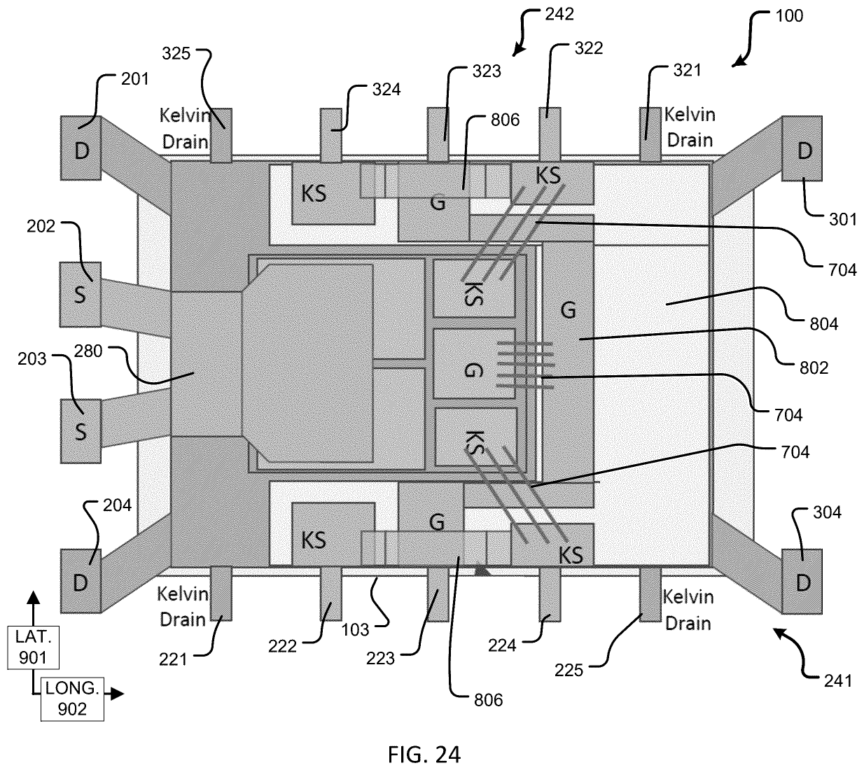

FIG. 24 illustrates a further more detailed bottom view of the exemplary power package according to FIG. 22.

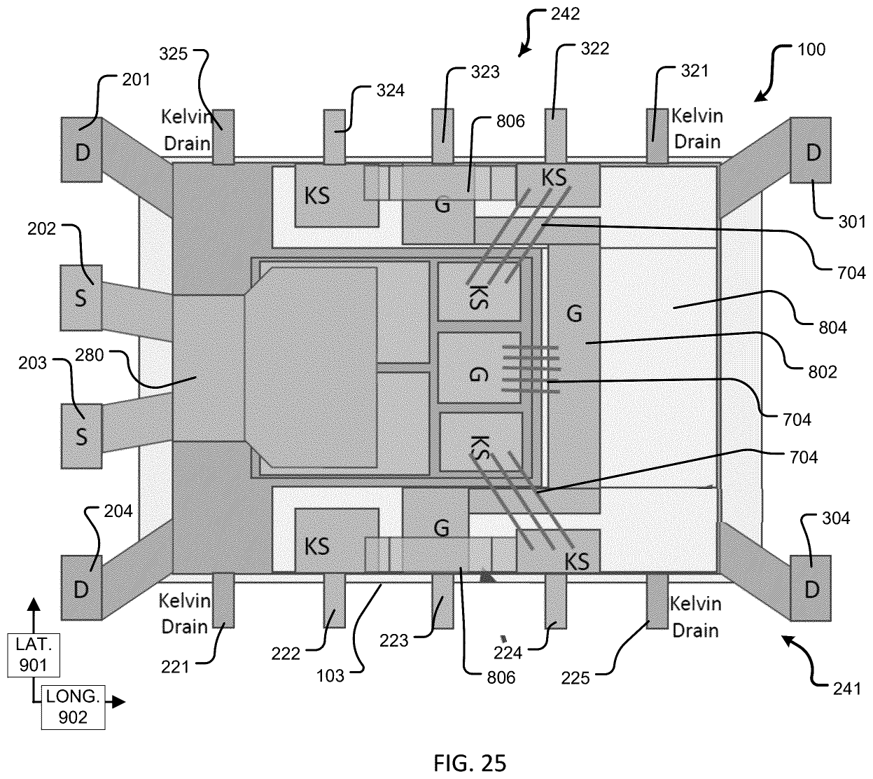

FIG. 25 illustrates a cross-sectional view of the exemplary power package according to FIG. 22.

In particular, FIG. 22 illustrates the power package 100 that may include the first power terminal 301, the second power terminal 302, the at least one power die 111, the first power terminal 201, the second power terminal 202, and/or the like. Further, the power package 100 illustrated in FIG. 22 may include the first signal terminal 321, the second signal terminal 322, the third signal terminal 323, the fourth signal terminal 324, and the fifth signal terminal 325. Additionally, the power package 100 illustrated in FIG. 22 may include the first signal terminal 221, the second signal terminal 222, the third signal terminal 223, the fourth signal terminal 224, and the fifth signal terminal 225.

Additionally, the power package 100 illustrated in FIG. 22 may include a gate interconnect 802. The gate interconnect 802 may connect between the third signal terminal 323 and the third signal terminal 223. In aspects, the gate interconnect 802 may be an electrically conductive material.

Further, the power package 100 illustrated in FIG. 22 may include insulation 804 arranged on the top substrate 600. In aspects, the insulation 804 may include a ceramic insulation material.

In aspects, the second signal terminal 322 and the fourth signal terminal 324 may be Kelvin source terminals, the third signal terminal 323 may be a gate terminal, and the first signal terminal 321 and the fifth signal terminal 325 may be a Kelvin drain terminal.

In aspects, the second signal terminal 222 and the fourth signal terminal 224 may be Kelvin source terminals, the third signal terminal 223 may be a gate terminal, and the first signal terminal 221 and the fifth signal terminal 225 may be a Kelvin drain terminal.

With reference to FIG. 23, the power package 100 may further include the at least one power die 111 arranged on the top substrate 600 as previously described. With reference to FIG. 24, the power package 100 may include the second power terminal 202 the third power terminal 203 and the at least one source bar 280 arranged on the at least one power die 111. Additionally, the power package 100 may include the at least one interconnect 704 extending from the at least one power die 111 to the second power terminals 232, the at least one power die 111 to the fourth signal terminal 224, and the at least one power die 111 to the gate interconnect 802. Additionally, the power package 100 may include at least one Kelvin source interconnect 806. In aspects, the power package 100 may implement the at least one Kelvin source interconnect 806 to connect between the fourth signal terminal 324 and the second signal terminal 322. In aspects, the power package 100 may implement the at least one Kelvin source interconnect 806 to connect between the fourth signal terminal 224 and the second signal terminal 222.

Aspects of the power package 100 illustrated in FIGS. 22-25 may optionally include any other features of the power package 100 as described and illustrated herein. Further, aspects of the power package 100 illustrated in FIGS. 22-25 and described therewith may optionally be implemented in any other implementations of the power package 100 as described and illustrated herein.

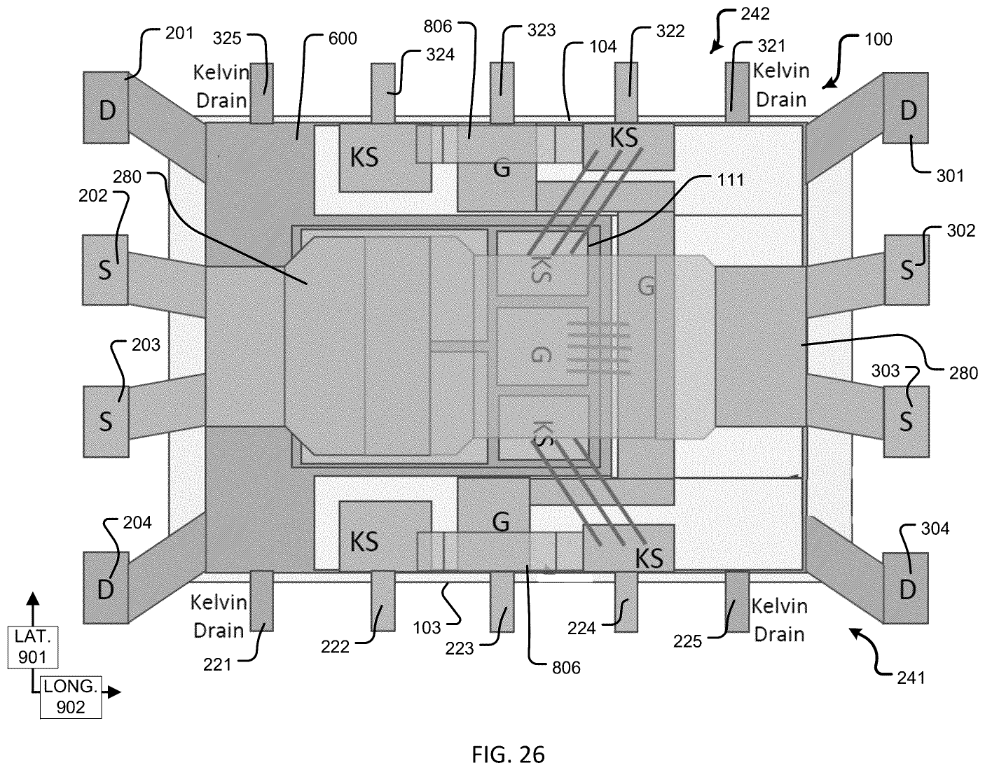

FIG. 26 illustrates a bottom view of an exemplary power package according to aspects of the disclosure.

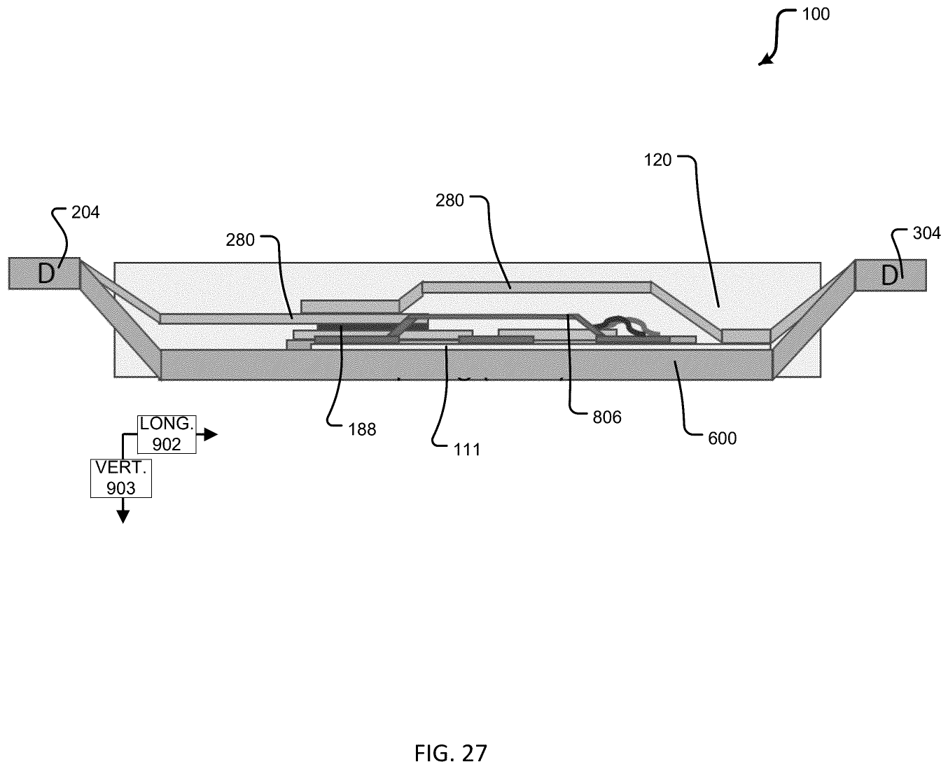

FIG. 27 illustrates a cross-sectional view of the exemplary power package according to FIG. 26.

In particular, FIG. 26 illustrates the power package 100 that may include the first power terminal 301, the second power terminal 302, the at least one power die 111, the first power terminal 201, the second power terminal 202, and/or the like. Further, the power package 100 illustrated in FIG. 26 may include the first signal terminal 321, the second signal terminal 322, the third signal terminal 323, the fourth signal terminal 324, and the fifth signal terminal 325. Additionally, the power package 100 illustrated in FIG. 26 may include the first signal terminal 221, the second signal terminal 222, the third signal terminal 223, the fourth signal terminal 224, and the fifth signal terminal 225.

Additionally, the power package 100 illustrated in FIG. 26 may include the gate interconnect 802, the insulation 804 arranged on the top substrate 600. In aspects, the insulation 804 may include a ceramic insulation material.

Further, the power package 100 illustrated in FIG. 26 may include a second implementation of the at least one source bar 280 that may connect to the second power terminal 302 and the third power terminal 303.

In aspects, the second signal terminal 322 and the fourth signal terminal 324 may be Kelvin source terminals, the third signal terminal 323 may be a gate terminal, and the first signal terminal 321 and the fifth signal terminal 325 may be a Kelvin drain terminal.

In aspects, the second signal terminal 222 and the fourth signal terminal 224 may be Kelvin source terminals, the third signal terminal 223 may be a gate terminal, and the first signal terminal 221 and the fifth signal terminal 225 may be a Kelvin drain terminal.

Aspects of the power package 100 illustrated in FIGS. 26 and 27 may optionally include any other features of the power package 100 as described and illustrated herein. Further, aspects of the power package 100 illustrated in FIGS. 26 and 27 and described therewith may optionally be implemented in any other implementations of the power package 100 as described and illustrated herein.

The at least one power die 111 may be implemented as one or more of the power semiconductor devices, a wide band-gap semiconductor device, an ultra-wideband device, a GaN based device, a LDMOS (Laterally-Diffused Metal-Oxide Semiconductor) device, a Metal Semiconductor Field-Effect Transistor (MESFET), a Metal Oxide Field Effect Transistor (MOSFET), a power MOSFET, a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, a diode, a power Schottky diode, a gate-controlled thyristor, a Metal Insulator Semiconductor Field Effect Transistor (MISFET), and/or the like. The at least one power die 111 may include a semiconductor layer structure that is formed using, for example, silicon and/or wide bandgap semiconductor materials such as silicon carbide and/or gallium nitride-based and/or aluminum nitride-based semiconductor systems (e.g., GaN, AlGaN, InGaN, AlN, etc.). Other wide bandgap materials may be used such as devices formed in other Group III-V semiconductor systems or in Group II-VI semiconductor systems.

A power semiconductor device may refer to devices that include one or more power semiconductor die that are designed to carry large currents and/or that are capable of blocking high voltages. Herein, a power semiconductor die refers to a semiconductor die that during normal operation can pass at least one Amp of current and/or block at least one hundred volts during reverse blocking operation. Power semiconductor die may be fabricated from wide bandgap semiconductor materials, such as silicon carbide (“SiC”) or gallium nitride (“GaN”) based semiconductor materials. A wide variety of power semiconductor die are known in the art, including, for example, power Metal Oxide Semiconductor Field Effect Transistors (“MOSFETs”), power insulated gate bipolar junction transistors (“IGBTs”), power Schottky diodes, and/or the like. Power semiconductor die are often packaged to provide a packaged power semiconductor device.

In aspects, the top substrate 600 may be implemented as a power substrate that includes a ceramic substrate. In aspects, the power substrate may include a lower metal cladding layer formed on a lower side of the ceramic substrate, and an upper metal cladding layer may be formed on the upper side of the ceramic substrate. As used herein, the term “power substrate” refers to a dielectric substrate that has a metal cladding layer on both sides thereof. In aspects, the power substrate may be an Active Metal Brazed (AMB) power substrate, which includes first and second metal braze layers that may be used to bond first and second metal cladding layers, respectively, to the ceramic substrate. In aspects, the power substrate may be a Substrate (or, more typically, a Direct Bonded Copper (DBC) power substrate, as the metal cladding layers may typically be copper layers).

In one aspect, the power package 100 may be implemented in a wide variety of power topologies, including half-bridge, full-bridge, three phase, booster, chopper, DC-DC converters, and like arrangements and/or topologies. In one aspect, one or more implementations of the power package 100 may be implemented in an application.

The power package 100 may be implemented in an application that may be a power system, a motor system, a motor drive, an automotive motor system, a charging system, an automotive charging system, a vehicle system, an industrial motor drive, an embedded motor drive, an uninterruptible power supply, an AC-DC power supply, a welder power supply, a military system, an inverter, an inverter for wind turbines, solar power panels, tidal power plants, electric vehicles (EVs), a converter, a solar inverter, a circuit breaker, a protection circuit, a DC-DC converter, an Off-Board DC Fast Charger for an electric vehicle (EV), an on-board DC/DC Converter for an electric vehicle (EV), an on-board battery charger for an electric vehicle (EV), an electric vehicle (EV) Powertrain/Main Inverter, an electric vehicle (EV) charging infrastructure, an electric traction motor, a motor drive for an electric motor, a commercial inductive heating system, an uninterruptible power system, a power system, a motor system, a motor drive, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, electric vehicles (EVs), a converter, solar inverters, circuit breakers, protection circuits, DC-DC converters, Off-Board DC Fast Chargers for electric vehicles (EVs) and the like, on-board DC/DC Converters for electric vehicles (EVs) and the like, on-board battery chargers for electric vehicles (EVs) and the like, electric vehicle (EV) Powertrains/Main Inverters, electric vehicle (EV) charging infrastructures, electric traction motors, motor drives for electric motors, commercial inductive heating systems, uninterruptible power systems, and/or the like.

Accordingly, the disclosure has provided a power package having an improved configuration.

The following are a number of nonlimiting EXAMPLES of aspects of the disclosure.

One EXAMPLE: a power package includes an assembly comprising a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first power terminals at the first power package side is symmetrical with respect to a location of the second power terminals at the second power package side.

The above-noted EXAMPLE may further include any one or a combination of more than one of the following EXAMPLES: The power package of the above-noted EXAMPLE includes a single power die, where the power package is configured as a power discrete package implementing the single power die. The power package of the above-noted EXAMPLE includes two power dies, where the power package is configured as a power discrete package implementing the two power dies. The power package of the above-noted EXAMPLE where the first power package side and the second power package side are opposing power package sides; and where the third power package side and the fourth power package side are opposing power package sides. The power package of the above-noted EXAMPLE where the first power package side and the second power package side are arranged between the third power package side and the fourth power package side. The power package of the above-noted EXAMPLE where the first signal terminals comprise one or more source kelvin terminals, kelvin drain terminals, gate terminals, and/or sensor terminals; and where the second signal terminals comprise one or more source kelvin terminals, kelvin drain terminals, gate terminals, and/or sensor terminals. The power package of the above-noted EXAMPLE includes an arrangement configured to provide topside cooling. The power package of the above-noted EXAMPLE includes an arrangement configured for surface mount implementations. The power package of the above-noted EXAMPLE where at least one of the first power terminals, the second power terminals, the first signal terminals, and the second signal terminals are configured in an arrangement for surface mount implementations. The power package of the above-noted EXAMPLE includes an arrangement configured for surface mounting to a circuit board. The power package of the above-noted EXAMPLE where at least one of the first power terminals, the second power terminals, the first signal terminals, and the second signal terminals are configured in an arrangement for surface mounting to a circuit board. The power package of the above-noted EXAMPLE includes: a top substrate; and at least one power die arranged under the top substrate. The power package of the above-noted EXAMPLE where the top substrate and the at least one power die are configured in an arrangement configured to provide topside cooling. The power package of the above-noted EXAMPLE includes risers arranged on the at least one power die. The power package of the above-noted EXAMPLE includes a source interconnect configured to be electrically connected to a source of at least one power die. The power package of the above-noted EXAMPLE where the source interconnect is connected to at least one of the first power terminals and/or at least one of the second power terminals. The power package of the above-noted EXAMPLE includes risers arranged on the at least one power die, where the risers are configured to be electrically connected the source interconnect. The power package of the above-noted EXAMPLE where the assembly comprises a configuration that is encapsulated in epoxy, overmolded, overmolded with epoxy, and/or potted, potted with a dielectric material. The power package of the above-noted EXAMPLE where one of the first power terminals and the second power terminals are configured to connect to the top substrate. The power package of the above-noted EXAMPLE where another one of the first power terminals and the second power terminals are configured to connect to the at least one power die. The power package of the above-noted EXAMPLE includes an insulation layer arranged on the top substrate, where at least one of the first signal terminals is arranged on the insulation layer; and where at least one of the second signal terminals is arranged on the insulation layer. The power package of the above-noted EXAMPLE includes: at least one signal interconnect, where an implementation of the at least one signal interconnect is connected to at least two of the first signal terminals; and where an implementation of the at least one signal interconnect is connected to at least two of the second signal terminals. The power package of the above-noted EXAMPLE where the first power terminals comprise a first power terminal, a second power terminal, a third power terminal, and a fourth power terminal; and where the second power terminals comprise a first power terminal, a second power terminal, a third power terminal, and a fourth power terminal. The configuration of the above-noted EXAMPLE where the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration. The configuration of the above-noted EXAMPLE includes a circuit board, where the at least one implementation of the power package being arranged on the circuit board. The power package of the above-noted EXAMPLE where a location of the first signal terminals at the third power package side is symmetrical with respect to a location of the second signal terminals at the fourth power package side. The power package of the above-noted EXAMPLE where a location of the first power terminals at the first power package side is symmetrical with respect to a location of the second power terminals at the second power package side. The power package of the above-noted EXAMPLE where the first power terminals are arranged symmetrically at the first power package side; and where the second power terminals are arranged symmetrically at the second power package side. The power package of the above-noted EXAMPLE where the first signal terminals are arranged symmetrically at the third power package side; and where the second signal terminals are arranged symmetrically at the fourth power package side. The power package of the above-noted EXAMPLE where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package of the above-noted EXAMPLE where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections.

One EXAMPLE: a power package includes an assembly comprising a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first signal terminals on third power package side is symmetrical with respect to a location of the second signal terminals on fourth power package side.

The above-noted EXAMPLE may further include any one or a combination of more than one of the following EXAMPLES: The power package of the above-noted EXAMPLE includes a single power die, where the power package is configured as a power discrete package implementing the single power die. The power package of the above-noted EXAMPLE includes two power dies, where the power package is configured as a power discrete package implementing the two power dies. The power package of the above-noted EXAMPLE where the first power package side and the second power package side are opposing power package sides; and where the third power package side and the fourth power package side are opposing power package sides. The power package of the above-noted EXAMPLE where the first power package side and the second power package side are arranged between the third power package side and the fourth power package side. The power package of the above-noted EXAMPLE where the first signal terminals comprise one or more source kelvin terminals, kelvin drain terminals, gate terminals, and/or sensor terminals; and where the second signal terminals comprise one or more source kelvin terminals, kelvin drain terminals, gate terminals, and/or sensor terminals. The power package of the above-noted EXAMPLE includes an arrangement configured to provide topside cooling. The power package of the above-noted EXAMPLE includes an arrangement configured for surface mount implementations. The power package of the above-noted EXAMPLE where at least one of the first power terminals, the second power terminals, the first signal terminals, and the second signal terminals are configured in an arrangement for surface mount implementations. The power package of the above-noted EXAMPLE includes an arrangement configured for surface mounting to a circuit board. The power package of the above-noted EXAMPLE where at least one of the first power terminals, the second power terminals, the first signal terminals, and the second signal terminals are configured in an arrangement for surface mounting to a circuit board. The power package of the above-noted EXAMPLE includes: a top substrate; and at least one power die arranged under the top substrate. The power package of the above-noted EXAMPLE where the top substrate and the at least one power die are configured in an arrangement configured to provide topside cooling. The power package of the above-noted EXAMPLE includes risers arranged on the at least one power die. The power package of the above-noted EXAMPLE includes a source interconnect configured to be electrically connected to a source of at least one power die. The power package of the above-noted EXAMPLE where the source interconnect is connected to at least one of the first power terminals and/or at least one of the second power terminals. The power package of the above-noted EXAMPLE includes risers arranged on the at least one power die, where the risers are configured to be electrically connected the source interconnect. The power package of the above-noted EXAMPLE where the assembly comprises a configuration that is encapsulated in epoxy, overmolded, overmolded with epoxy, and/or potted, potted with a dielectric material. The power package of the above-noted EXAMPLE where one of the first power terminals and the second power terminals are configured to connect to the top substrate. The power package of the above-noted EXAMPLE where another one of the first power terminals and the second power terminals are configured to connect to the at least one power die. The power package of the above-noted EXAMPLE includes an insulation layer arranged on the top substrate, where at least one of the first signal terminals is arranged on the insulation layer; and where at least one of the second signal terminals is arranged on the insulation layer. The power package of the above-noted EXAMPLE includes: at least one signal interconnect, where an implementation of the at least one signal interconnect is connected to at least two of the first signal terminals; and where an implementation of the at least one signal interconnect is connected to at least two of the second signal terminals. The power package of the above-noted EXAMPLE where the first power terminals comprise a first power terminal, a second power terminal, a third power terminal, and a fourth power terminal; and where the second power terminals comprise a first power terminal, a second power terminal, a third power terminal, and a fourth power terminal. The configuration of the above-noted EXAMPLE where the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration. The configuration of the above-noted EXAMPLE includes a circuit board, where the at least one implementation of the power package being arranged on the circuit board. The power package of the above-noted EXAMPLE where a location of the first signal terminals at the third power package side is symmetrical with respect to a location of the second signal terminals at the fourth power package side. The power package of the above-noted EXAMPLE where a location of the first power terminals at the first power package side is symmetrical with respect to a location of the second power terminals at the second power package side. The power package of the above-noted EXAMPLE where the first power terminals are arranged symmetrically at the first power package side; and where the second power terminals are arranged symmetrically at the second power package side. The power package of the above-noted EXAMPLE where the first signal terminals are arranged symmetrically at the third power package side; and where the second signal terminals are arranged symmetrically at the fourth power package side. The power package of the above-noted EXAMPLE where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package of the above-noted EXAMPLE where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections.

One EXAMPLE: a power package includes an assembly comprising a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first signal terminals on third power package side is symmetrical with respect to one side of third power package side and another side of third power package side. The power package moreover includes where a location of the second signal terminals on fourth power package side is symmetrical with respect to one side of fourth power package side and another side of fourth power package side.

The above-noted EXAMPLE may further include any one or a combination of more than one of the following EXAMPLES: The power package of the above-noted EXAMPLE includes a single power die, where the power package is configured as a power discrete package implementing the single power die. The power package of the above-noted EXAMPLE includes two power dies, where the power package is configured as a power discrete package implementing the two power dies. The power package of the above-noted EXAMPLE where the first power package side and the second power package side are opposing power package sides; and where the third power package side and the fourth power package side are opposing power package sides. The power package of the above-noted EXAMPLE where the first power package side and the second power package side are arranged between the third power package side and the fourth power package side. The power package of the above-noted EXAMPLE where the first signal terminals comprise one or more source kelvin terminals, kelvin drain terminals, gate terminals, and/or sensor terminals; and where the second signal terminals comprise one or more source kelvin terminals, kelvin drain terminals, gate terminals, and/or sensor terminals. The power package of the above-noted EXAMPLE includes an arrangement configured to provide topside cooling. The power package of the above-noted EXAMPLE includes an arrangement configured for surface mount implementations. The power package of the above-noted EXAMPLE where at least one of the first power terminals, the second power terminals, the first signal terminals, and the second signal terminals are configured in an arrangement for surface mount implementations. The power package of the above-noted EXAMPLE includes an arrangement configured for surface mounting to a circuit board. The power package of the above-noted EXAMPLE where at least one of the first power terminals, the second power terminals, the first signal terminals, and the second signal terminals are configured in an arrangement for surface mounting to a circuit board. The power package of the above-noted EXAMPLE includes: a top substrate; and at least one power die arranged under the top substrate. The power package of the above-noted EXAMPLE where the top substrate and the at least one power die are configured in an arrangement configured to provide topside cooling. The power package of the above-noted EXAMPLE includes risers arranged on the at least one power die. The power package of the above-noted EXAMPLE includes a source interconnect configured to be electrically connected to a source of at least one power die. The power package of the above-noted EXAMPLE where the source interconnect is connected to at least one of the first power terminals and/or at least one of the second power terminals. The power package of the above-noted EXAMPLE includes risers arranged on the at least one power die, where the risers are configured to be electrically connected the source interconnect. The power package of the above-noted EXAMPLE where the assembly comprises a configuration that is encapsulated in epoxy, overmolded, overmolded with epoxy, and/or potted, potted with a dielectric material. The power package of the above-noted EXAMPLE where one of the first power terminals and the second power terminals are configured to connect to the top substrate. The power package of the above-noted EXAMPLE where another one of the first power terminals and the second power terminals are configured to connect to the at least one power die. The power package of the above-noted EXAMPLE includes an insulation layer arranged on the top substrate, where at least one of the first signal terminals is arranged on the insulation layer; and where at least one of the second signal terminals is arranged on the insulation layer. The power package of the above-noted EXAMPLE includes: at least one signal interconnect, where an implementation of the at least one signal interconnect is connected to at least two of the first signal terminals; and where an implementation of the at least one signal interconnect is connected to at least two of the second signal terminals. The power package of the above-noted EXAMPLE where the first power terminals comprise a first power terminal, a second power terminal, a third power terminal, and a fourth power terminal; and where the second power terminals comprise a first power terminal, a second power terminal, a third power terminal, and a fourth power terminal. The configuration of the above-noted EXAMPLE where the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration. The configuration of the above-noted EXAMPLE includes a circuit board, where the at least one implementation of the power package being arranged on the circuit board. The power package of the above-noted EXAMPLE where a location of the first signal terminals at the third power package side is symmetrical with respect to a location of the second signal terminals at the fourth power package side. The power package of the above-noted EXAMPLE where a location of the first power terminals at the first power package side is symmetrical with respect to a location of the second power terminals at the second power package side. The power package of the above-noted EXAMPLE where the first power terminals are arranged symmetrically at the first power package side; and where the second power terminals are arranged symmetrically at the second power package side. The power package of the above-noted EXAMPLE where the first signal terminals are arranged symmetrically at the third power package side; and where the second signal terminals are arranged symmetrically at the fourth power package side. The power package of the above-noted EXAMPLE where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package of the above-noted EXAMPLE where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections.

One EXAMPLE: a power package includes an assembly comprising a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first signal terminals on third power package side is symmetrical with respect to one side of third power package side and another side of third power package side. The power package moreover includes where a location of the second signal terminals on fourth power package side is symmetrical with respect to one side of fourth power package side and another side of fourth power package side.

The above-noted EXAMPLE may further include any one or a combination of more than one of the following EXAMPLES: The power package of the above-noted EXAMPLE includes a single power die, where the power package is configured as a power discrete package implementing the single power die. The power package of the above-noted EXAMPLE includes two power dies, where the power package is configured as a power discrete package implementing the two power dies. The power package of the above-noted EXAMPLE where the first power package side and the second power package side are opposing power package sides; and where the third power package side and the fourth power package side are opposing power package sides. The power package of the above-noted EXAMPLE where the first power package side and the second power package side are arranged between the third power package side and the fourth power package side. The power package of the above-noted EXAMPLE where the first signal terminals comprise one or more source kelvin terminals, kelvin drain terminals, gate terminals, and/or sensor terminals; and where the second signal terminals comprise one or more source kelvin terminals, kelvin drain terminals, gate terminals, and/or sensor terminals. The power package of the above-noted EXAMPLE includes an arrangement configured to provide topside cooling. The power package of the above-noted EXAMPLE includes an arrangement configured for surface mount implementations. The power package of the above-noted EXAMPLE where at least one of the first power terminals, the second power terminals, the first signal terminals, and the second signal terminals are configured in an arrangement for surface mount implementations. The power package of the above-noted EXAMPLE includes an arrangement configured for surface mounting to a circuit board. The power package of the above-noted EXAMPLE where at least one of the first power terminals, the second power terminals, the first signal terminals, and the second signal terminals are configured in an arrangement for surface mounting to a circuit board. The power package of the above-noted EXAMPLE includes: a top substrate; and at least one power die arranged under the top substrate. The power package of the above-noted EXAMPLE where the top substrate and the at least one power die are configured in an arrangement configured to provide topside cooling. The power package of the above-noted EXAMPLE includes risers arranged on the at least one power die. The power package of the above-noted EXAMPLE includes a source interconnect configured to be electrically connected to a source of at least one power die. The power package of the above-noted EXAMPLE where the source interconnect is connected to at least one of the first power terminals and/or at least one of the second power terminals. The power package of the above-noted EXAMPLE includes risers arranged on the at least one power die, where the risers are configured to be electrically connected the source interconnect. The power package of the above-noted EXAMPLE where the assembly comprises a configuration that is encapsulated in epoxy, overmolded, overmolded with epoxy, and/or potted, potted with a dielectric material. The power package of the above-noted EXAMPLE where one of the first power terminals and the second power terminals are configured to connect to the top substrate. The power package of the above-noted EXAMPLE where another one of the first power terminals and the second power terminals are configured to connect to the at least one power die. The power package of the above-noted EXAMPLE includes an insulation layer arranged on the top substrate, where at least one of the first signal terminals is arranged on the insulation layer; and where at least one of the second signal terminals is arranged on the insulation layer. The power package of the above-noted EXAMPLE includes: at least one signal interconnect, where an implementation of the at least one signal interconnect is connected to at least two of the first signal terminals; and where an implementation of the at least one signal interconnect is connected to at least two of the second signal terminals. The power package of the above-noted EXAMPLE where the first power terminals comprise a first power terminal, a second power terminal, a third power terminal, and a fourth power terminal; and where the second power terminals comprise a first power terminal, a second power terminal, a third power terminal, and a fourth power terminal. The configuration of the above-noted EXAMPLE where the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration. The configuration of the above-noted EXAMPLE includes a circuit board, where the at least one implementation of the power package being arranged on the circuit board. The power package of the above-noted EXAMPLE where a location of the first signal terminals at the third power package side is symmetrical with respect to a location of the second signal terminals at the fourth power package side. The power package of the above-noted EXAMPLE where a location of the first power terminals at the first power package side is symmetrical with respect to a location of the second power terminals at the second power package side. The power package of the above-noted EXAMPLE where the first power terminals are arranged symmetrically at the first power package side; and where the second power terminals are arranged symmetrically at the second power package side. The power package of the above-noted EXAMPLE where the first signal terminals are arranged symmetrically at the third power package side; and where the second signal terminals are arranged symmetrically at the fourth power package side. The power package of the above-noted EXAMPLE where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package of the above-noted EXAMPLE where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections.

One EXAMPLE: a power package includes an assembly comprising a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where a location of the first signal terminals on third power package side is symmetrical with respect to a location of the second signal terminals on fourth power package side.

The above-noted EXAMPLE may further include any one or a combination of more than one of the following EXAMPLES: The power package of the above-noted EXAMPLE includes a single power die, where the power package is configured as a power discrete package implementing the single power die. The power package of the above-noted EXAMPLE includes two power dies, where the power package is configured as a power discrete package implementing the two power dies. The power package of the above-noted EXAMPLE where the first power package side and the second power package side are opposing power package sides; and where the third power package side and the fourth power package side are opposing power package sides. The power package of the above-noted EXAMPLE where the first power package side and the second power package side are arranged between the third power package side and the fourth power package side. The power package of the above-noted EXAMPLE where the first signal terminals comprise one or more source kelvin terminals, kelvin drain terminals, gate terminals, and/or sensor terminals; and where the second signal terminals comprise one or more source kelvin terminals, kelvin drain terminals, gate terminals, and/or sensor terminals. The power package of the above-noted EXAMPLE includes an arrangement configured to provide topside cooling. The power package of the above-noted EXAMPLE includes an arrangement configured for surface mount implementations. The power package of the above-noted EXAMPLE where at least one of the first power terminals, the second power terminals, the first signal terminals, and the second signal terminals are configured in an arrangement for surface mount implementations. The power package of the above-noted EXAMPLE includes an arrangement configured for surface mounting to a circuit board. The power package of the above-noted EXAMPLE where at least one of the first power terminals, the second power terminals, the first signal terminals, and the second signal terminals are configured in an arrangement for surface mounting to a circuit board. The power package of the above-noted EXAMPLE includes: a top substrate; and at least one power die arranged under the top substrate. The power package of the above-noted EXAMPLE where the top substrate and the at least one power die are configured in an arrangement configured to provide topside cooling. The power package of the above-noted EXAMPLE includes risers arranged on the at least one power die. The power package of the above-noted EXAMPLE includes a source interconnect configured to be electrically connected to a source of at least one power die. The power package of the above-noted EXAMPLE where the source interconnect is connected to at least one of the first power terminals and/or at least one of the second power terminals. The power package of the above-noted EXAMPLE includes risers arranged on the at least one power die, where the risers are configured to be electrically connected the source interconnect. The power package of the above-noted EXAMPLE where the assembly comprises a configuration that is encapsulated in epoxy, overmolded, overmolded with epoxy, and/or potted, potted with a dielectric material. The power package of the above-noted EXAMPLE where one of the first power terminals and the second power terminals are configured to connect to the top substrate. The power package of the above-noted EXAMPLE where another one of the first power terminals and the second power terminals are configured to connect to the at least one power die. The power package of the above-noted EXAMPLE includes an insulation layer arranged on the top substrate, where at least one of the first signal terminals is arranged on the insulation layer; and where at least one of the second signal terminals is arranged on the insulation layer. The power package of the above-noted EXAMPLE includes: at least one signal interconnect, where an implementation of the at least one signal interconnect is connected to at least two of the first signal terminals; and where an implementation of the at least one signal interconnect is connected to at least two of the second signal terminals. The power package of the above-noted EXAMPLE where the first power terminals comprise a first power terminal, a second power terminal, a third power terminal, and a fourth power terminal; and where the second power terminals comprise a first power terminal, a second power terminal, a third power terminal, and a fourth power terminal. The configuration of the above-noted EXAMPLE where the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration. The configuration of the above-noted EXAMPLE includes a circuit board, where the at least one implementation of the power package being arranged on the circuit board. The power package of the above-noted EXAMPLE where a location of the first signal terminals at the third power package side is symmetrical with respect to a location of the second signal terminals at the fourth power package side. The power package of the above-noted EXAMPLE where a location of the first power terminals at the first power package side is symmetrical with respect to a location of the second power terminals at the second power package side. The power package of the above-noted EXAMPLE where the first power terminals are arranged symmetrically at the first power package side; and where the second power terminals are arranged symmetrically at the second power package side. The power package of the above-noted EXAMPLE where the first signal terminals are arranged symmetrically at the third power package side; and where the second signal terminals are arranged symmetrically at the fourth power package side. The power package of the above-noted EXAMPLE where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package of the above-noted EXAMPLE where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections.

One EXAMPLE: a power package includes an assembly comprising a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where an arrangement and location of the first power terminals is symmetrical about a lateral axis of symmetry with respect to an arrangement and location of the second power terminals.

The above-noted EXAMPLE may further include any one or a combination of more than one of the following EXAMPLES: The power package of the above-noted EXAMPLE includes a single power die, where the power package is configured as a power discrete package implementing the single power die. The power package of the above-noted EXAMPLE includes two power dies, where the power package is configured as a power discrete package implementing the two power dies. The power package of the above-noted EXAMPLE where the first power package side and the second power package side are opposing power package sides; and where the third power package side and the fourth power package side are opposing power package sides. The power package of the above-noted EXAMPLE where the first power package side and the second power package side are arranged between the third power package side and the fourth power package side. The power package of the above-noted EXAMPLE where the first signal terminals comprise one or more source kelvin terminals, kelvin drain terminals, gate terminals, and/or sensor terminals; and where the second signal terminals comprise one or more source kelvin terminals, kelvin drain terminals, gate terminals, and/or sensor terminals. The power package of the above-noted EXAMPLE includes an arrangement configured to provide topside cooling. The power package of the above-noted EXAMPLE includes an arrangement configured for surface mount implementations. The power package of the above-noted EXAMPLE where at least one of the first power terminals, the second power terminals, the first signal terminals, and the second signal terminals are configured in an arrangement for surface mount implementations. The power package of the above-noted EXAMPLE includes an arrangement configured for surface mounting to a circuit board. The power package of the above-noted EXAMPLE where at least one of the first power terminals, the second power terminals, the first signal terminals, and the second signal terminals are configured in an arrangement for surface mounting to a circuit board. The power package of the above-noted EXAMPLE includes: a top substrate; and at least one power die arranged under the top substrate. The power package of the above-noted EXAMPLE where the top substrate and the at least one power die are configured in an arrangement configured to provide topside cooling. The power package of the above-noted EXAMPLE includes risers arranged on the at least one power die. The power package of the above-noted EXAMPLE includes a source interconnect configured to be electrically connected to a source of at least one power die. The power package of the above-noted EXAMPLE where the source interconnect is connected to at least one of the first power terminals and/or at least one of the second power terminals. The power package of the above-noted EXAMPLE includes risers arranged on the at least one power die, where the risers are configured to be electrically connected the source interconnect. The power package of the above-noted EXAMPLE where the assembly comprises a configuration that is encapsulated in epoxy, overmolded, overmolded with epoxy, and/or potted, potted with a dielectric material. The power package of the above-noted EXAMPLE where one of the first power terminals and the second power terminals are configured to connect to the top substrate. The power package of the above-noted EXAMPLE where another one of the first power terminals and the second power terminals are configured to connect to the at least one power die. The power package of the above-noted EXAMPLE includes an insulation layer arranged on the top substrate, where at least one of the first signal terminals is arranged on the insulation layer; and where at least one of the second signal terminals is arranged on the insulation layer. The power package of the above-noted EXAMPLE includes: at least one signal interconnect, where an implementation of the at least one signal interconnect is connected to at least two of the first signal terminals; and where an implementation of the at least one signal interconnect is connected to at least two of the second signal terminals. The power package of the above-noted EXAMPLE where the first power terminals comprise a first power terminal, a second power terminal, a third power terminal, and a fourth power terminal; and where the second power terminals comprise a first power terminal, a second power terminal, a third power terminal, and a fourth power terminal. The configuration of the above-noted EXAMPLE where the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration. The configuration of the above-noted EXAMPLE includes a circuit board, where the at least one implementation of the power package being arranged on the circuit board. The power package of the above-noted EXAMPLE where a location of the first signal terminals at the third power package side is symmetrical with respect to a location of the second signal terminals at the fourth power package side. The power package of the above-noted EXAMPLE where a location of the first power terminals at the first power package side is symmetrical with respect to a location of the second power terminals at the second power package side. The power package of the above-noted EXAMPLE where the first power terminals are arranged symmetrically at the first power package side; and where the second power terminals are arranged symmetrically at the second power package side. The power package of the above-noted EXAMPLE where the first signal terminals are arranged symmetrically at the third power package side; and where the second signal terminals are arranged symmetrically at the fourth power package side. The power package of the above-noted EXAMPLE where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package of the above-noted EXAMPLE where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections.

One EXAMPLE: a power package includes an assembly comprising a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where an arrangement and location of the first power terminals is symmetrical about a longitudinal axis of symmetry with respect to an arrangement and location of the second power terminals.

The above-noted EXAMPLE may further include any one or a combination of more than one of the following EXAMPLES: The power package of the above-noted EXAMPLE includes a single power die, where the power package is configured as a power discrete package implementing the single power die. The power package of the above-noted EXAMPLE includes two power dies, where the power package is configured as a power discrete package implementing the two power dies. The power package of the above-noted EXAMPLE where the first power package side and the second power package side are opposing power package sides; and where the third power package side and the fourth power package side are opposing power package sides. The power package of the above-noted EXAMPLE where the first power package side and the second power package side are arranged between the third power package side and the fourth power package side. The power package of the above-noted EXAMPLE where the first signal terminals comprise one or more source kelvin terminals, kelvin drain terminals, gate terminals, and/or sensor terminals; and where the second signal terminals comprise one or more source kelvin terminals, kelvin drain terminals, gate terminals, and/or sensor terminals. The power package of the above-noted EXAMPLE includes an arrangement configured to provide topside cooling. The power package of the above-noted EXAMPLE includes an arrangement configured for surface mount implementations. The power package of the above-noted EXAMPLE where at least one of the first power terminals, the second power terminals, the first signal terminals, and the second signal terminals are configured in an arrangement for surface mount implementations. The power package of the above-noted EXAMPLE includes an arrangement configured for surface mounting to a circuit board. The power package of the above-noted EXAMPLE where at least one of the first power terminals, the second power terminals, the first signal terminals, and the second signal terminals are configured in an arrangement for surface mounting to a circuit board. The power package of the above-noted EXAMPLE includes: a top substrate; and at least one power die arranged under the top substrate. The power package of the above-noted EXAMPLE where the top substrate and the at least one power die are configured in an arrangement configured to provide topside cooling. The power package of the above-noted EXAMPLE includes risers arranged on the at least one power die. The power package of the above-noted EXAMPLE includes a source interconnect configured to be electrically connected to a source of at least one power die. The power package of the above-noted EXAMPLE where the source interconnect is connected to at least one of the first power terminals and/or at least one of the second power terminals. The power package of the above-noted EXAMPLE includes risers arranged on the at least one power die, where the risers are configured to be electrically connected the source interconnect. The power package of the above-noted EXAMPLE where the assembly comprises a configuration that is encapsulated in epoxy, overmolded, overmolded with epoxy, and/or potted, potted with a dielectric material. The power package of the above-noted EXAMPLE where one of the first power terminals and the second power terminals are configured to connect to the top substrate. The power package of the above-noted EXAMPLE where another one of the first power terminals and the second power terminals are configured to connect to the at least one power die. The power package of the above-noted EXAMPLE includes an insulation layer arranged on the top substrate, where at least one of the first signal terminals is arranged on the insulation layer; and where at least one of the second signal terminals is arranged on the insulation layer. The power package of the above-noted EXAMPLE includes: at least one signal interconnect, where an implementation of the at least one signal interconnect is connected to at least two of the first signal terminals; and where an implementation of the at least one signal interconnect is connected to at least two of the second signal terminals. The power package of the above-noted EXAMPLE where the first power terminals comprise a first power terminal, a second power terminal, a third power terminal, and a fourth power terminal; and where the second power terminals comprise a first power terminal, a second power terminal, a third power terminal, and a fourth power terminal. The configuration of the above-noted EXAMPLE where the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration. The configuration of the above-noted EXAMPLE includes a circuit board, where the at least one implementation of the power package being arranged on the circuit board. The power package of the above-noted EXAMPLE where a location of the first signal terminals at the third power package side is symmetrical with respect to a location of the second signal terminals at the fourth power package side. The power package of the above-noted EXAMPLE where a location of the first power terminals at the first power package side is symmetrical with respect to a location of the second power terminals at the second power package side. The power package of the above-noted EXAMPLE where the first power terminals are arranged symmetrically at the first power package side; and where the second power terminals are arranged symmetrically at the second power package side. The power package of the above-noted EXAMPLE where the first signal terminals are arranged symmetrically at the third power package side; and where the second signal terminals are arranged symmetrically at the fourth power package side. The power package of the above-noted EXAMPLE where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package of the above-noted EXAMPLE where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections.

One EXAMPLE: a power package includes an assembly comprising a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where an arrangement and location of the first signal terminals is symmetrical about a longitudinal axis of symmetry with respect to an arrangement and location of the second signal terminals.

The above-noted EXAMPLE may further include any one or a combination of more than one of the following EXAMPLES: The power package of the above-noted EXAMPLE includes a single power die, where the power package is configured as a power discrete package implementing the single power die. The power package of the above-noted EXAMPLE includes two power dies, where the power package is configured as a power discrete package implementing the two power dies. The power package of the above-noted EXAMPLE where the first power package side and the second power package side are opposing power package sides; and where the third power package side and the fourth power package side are opposing power package sides. The power package of the above-noted EXAMPLE where the first power package side and the second power package side are arranged between the third power package side and the fourth power package side. The power package of the above-noted EXAMPLE where the first signal terminals comprise one or more source kelvin terminals, kelvin drain terminals, gate terminals, and/or sensor terminals; and where the second signal terminals comprise one or more source kelvin terminals, kelvin drain terminals, gate terminals, and/or sensor terminals. The power package of the above-noted EXAMPLE includes an arrangement configured to provide topside cooling. The power package of the above-noted EXAMPLE includes an arrangement configured for surface mount implementations. The power package of the above-noted EXAMPLE where at least one of the first power terminals, the second power terminals, the first signal terminals, and the second signal terminals are configured in an arrangement for surface mount implementations. The power package of the above-noted EXAMPLE includes an arrangement configured for surface mounting to a circuit board. The power package of the above-noted EXAMPLE where at least one of the first power terminals, the second power terminals, the first signal terminals, and the second signal terminals are configured in an arrangement for surface mounting to a circuit board. The power package of the above-noted EXAMPLE includes: a top substrate; and at least one power die arranged under the top substrate. The power package of the above-noted EXAMPLE where the top substrate and the at least one power die are configured in an arrangement configured to provide topside cooling. The power package of the above-noted EXAMPLE includes risers arranged on the at least one power die. The power package of the above-noted EXAMPLE includes a source interconnect configured to be electrically connected to a source of at least one power die. The power package of the above-noted EXAMPLE where the source interconnect is connected to at least one of the first power terminals and/or at least one of the second power terminals. The power package of the above-noted EXAMPLE includes risers arranged on the at least one power die, where the risers are configured to be electrically connected the source interconnect. The power package of the above-noted EXAMPLE where the assembly comprises a configuration that is encapsulated in epoxy, overmolded, overmolded with epoxy, and/or potted, potted with a dielectric material. The power package of the above-noted EXAMPLE where one of the first power terminals and the second power terminals are configured to connect to the top substrate. The power package of the above-noted EXAMPLE where another one of the first power terminals and the second power terminals are configured to connect to the at least one power die. The power package of the above-noted EXAMPLE includes an insulation layer arranged on the top substrate, where at least one of the first signal terminals is arranged on the insulation layer; and where at least one of the second signal terminals is arranged on the insulation layer. The power package of the above-noted EXAMPLE includes: at least one signal interconnect, where an implementation of the at least one signal interconnect is connected to at least two of the first signal terminals; and where an implementation of the at least one signal interconnect is connected to at least two of the second signal terminals. The power package of the above-noted EXAMPLE where the first power terminals comprise a first power terminal, a second power terminal, a third power terminal, and a fourth power terminal; and where the second power terminals comprise a first power terminal, a second power terminal, a third power terminal, and a fourth power terminal. The configuration of the above-noted EXAMPLE where the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration. The configuration of the above-noted EXAMPLE includes a circuit board, where the at least one implementation of the power package being arranged on the circuit board. The power package of the above-noted EXAMPLE where a location of the first signal terminals at the third power package side is symmetrical with respect to a location of the second signal terminals at the fourth power package side. The power package of the above-noted EXAMPLE where a location of the first power terminals at the first power package side is symmetrical with respect to a location of the second power terminals at the second power package side. The power package of the above-noted EXAMPLE where the first power terminals are arranged symmetrically at the first power package side; and where the second power terminals are arranged symmetrically at the second power package side. The power package of the above-noted EXAMPLE where the first signal terminals are arranged symmetrically at the third power package side; and where the second signal terminals are arranged symmetrically at the fourth power package side. The power package of the above-noted EXAMPLE where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package of the above-noted EXAMPLE where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections.

One EXAMPLE: a power package includes an assembly comprising a first power package side, a second power package side, a third power package side, and a fourth power package side. The power package in addition includes first power terminals arranged at the first power package side. The power package moreover includes second power terminals arranged at the second power package side. The power package also includes first signal terminals arranged at the third power package side. The power package further includes second signal terminals arranged at the fourth power package side. The power package in addition includes where an arrangement and location of the first signal terminals is symmetrical about a lateral axis of symmetry with respect to an arrangement and location of the second signal terminals.

The above-noted EXAMPLE may further include any one or a combination of more than one of the following EXAMPLES: The power package of the above-noted EXAMPLE includes a single power die, where the power package is configured as a power discrete package implementing the single power die. The power package of the above-noted EXAMPLE includes two power dies, where the power package is configured as a power discrete package implementing the two power dies. The power package of the above-noted EXAMPLE where the first power package side and the second power package side are opposing power package sides; and where the third power package side and the fourth power package side are opposing power package sides. The power package of the above-noted EXAMPLE where the first power package side and the second power package side are arranged between the third power package side and the fourth power package side. The power package of the above-noted EXAMPLE where the first signal terminals comprise one or more source kelvin terminals, kelvin drain terminals, gate terminals, and/or sensor terminals; and where the second signal terminals comprise one or more source kelvin terminals, kelvin drain terminals, gate terminals, and/or sensor terminals. The power package of the above-noted EXAMPLE includes an arrangement configured to provide topside cooling. The power package of the above-noted EXAMPLE includes an arrangement configured for surface mount implementations. The power package of the above-noted EXAMPLE where at least one of the first power terminals, the second power terminals, the first signal terminals, and the second signal terminals are configured in an arrangement for surface mount implementations. The power package of the above-noted EXAMPLE includes an arrangement configured for surface mounting to a circuit board. The power package of the above-noted EXAMPLE where at least one of the first power terminals, the second power terminals, the first signal terminals, and the second signal terminals are configured in an arrangement for surface mounting to a circuit board. The power package of the above-noted EXAMPLE includes: a top substrate; and at least one power die arranged under the top substrate. The power package of the above-noted EXAMPLE where the top substrate and the at least one power die are configured in an arrangement configured to provide topside cooling. The power package of the above-noted EXAMPLE includes risers arranged on the at least one power die. The power package of the above-noted EXAMPLE includes a source interconnect configured to be electrically connected to a source of at least one power die. The power package of the above-noted EXAMPLE where the source interconnect is connected to at least one of the first power terminals and/or at least one of the second power terminals. The power package of the above-noted EXAMPLE includes risers arranged on the at least one power die, where the risers are configured to be electrically connected the source interconnect. The power package of the above-noted EXAMPLE where the assembly comprises a configuration that is encapsulated in epoxy, overmolded, overmolded with epoxy, and/or potted, potted with a dielectric material. The power package of the above-noted EXAMPLE where one of the first power terminals and the second power terminals are configured to connect to the top substrate. The power package of the above-noted EXAMPLE where another one of the first power terminals and the second power terminals are configured to connect to the at least one power die. The power package of the above-noted EXAMPLE includes an insulation layer arranged on the top substrate, where at least one of the first signal terminals is arranged on the insulation layer; and where at least one of the second signal terminals is arranged on the insulation layer. The power package of the above-noted EXAMPLE includes: at least one signal interconnect, where an implementation of the at least one signal interconnect is connected to at least two of the first signal terminals; and where an implementation of the at least one signal interconnect is connected to at least two of the second signal terminals. The power package of the above-noted EXAMPLE where the first power terminals comprise a first power terminal, a second power terminal, a third power terminal, and a fourth power terminal; and where the second power terminals comprise a first power terminal, a second power terminal, a third power terminal, and a fourth power terminal. The configuration of the above-noted EXAMPLE where the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration. The configuration of the above-noted EXAMPLE includes a circuit board, where the at least one implementation of the power package being arranged on the circuit board. The power package of the above-noted EXAMPLE where a location of the first signal terminals at the third power package side is symmetrical with respect to a location of the second signal terminals at the fourth power package side. The power package of the above-noted EXAMPLE where a location of the first power terminals at the first power package side is symmetrical with respect to a location of the second power terminals at the second power package side. The power package of the above-noted EXAMPLE where the first power terminals are arranged symmetrically at the first power package side; and where the second power terminals are arranged symmetrically at the second power package side. The power package of the above-noted EXAMPLE where the first signal terminals are arranged symmetrically at the third power package side; and where the second signal terminals are arranged symmetrically at the fourth power package side. The power package of the above-noted EXAMPLE where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package of the above-noted EXAMPLE where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a solid mass of material by heat and/or pressure. The sintering process may operate without melting the material to the point of liquefaction. The sintering process may include sintering of metallic powders. The sintering process may include sintering in a vacuum. The sintering process may include sintering with the use of a protective gas.

The eutectic bonding of the disclosure may utilize a bonding process with an intermediate metal layer that may form a eutectic system. The eutectic system may be used between surfaces to be connected. The eutectic bonding may utilize eutectic metals that may be alloys that transform from solid to liquid state, or from liquid to solid state, at a specific composition and temperature without passing a two-phase equilibrium. The eutectic alloys may be deposited by sputtering, dual source evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A power package comprising:
an assembly comprising a first power package side, a second power package side, a third power package side, and a fourth power package side;
first power terminals arranged at the first power package side;
second power terminals arranged at the second power package side;
first signal terminals arranged at the third power package side; and
second signal terminals arranged at the fourth power package side,
wherein a location of the first power terminals at the first power package side is symmetrical with respect to a location of the second power terminals at the second power package side.

2. The power package according to claim 1, further comprising a single power die, wherein the power package is configured as a power discrete package implementing the single power die.

3. The power package according to claim 1, further comprising two power dies, wherein the power package is configured as a power discrete package implementing the two power dies.

4. The power package according to claim 1, wherein the first power package side and the second power package side are opposing power package sides; and wherein the third power package side and the fourth power package side are opposing power package sides.

5. (canceled)

6. The power package according to claim 1,
wherein the first signal terminals comprise one or more source kelvin terminals, kelvin drain terminals, gate terminals, and/or sensor terminals; and
wherein the second signal terminals comprise one or more source kelvin terminals, kelvin drain terminals, gate terminals, and/or sensor terminals.

7. The power package according to claim 1, further comprising an arrangement configured to provide topside cooling.

8. The power package according to claim 1, further comprising an arrangement configured for surface mount implementations.

9.-11. (canceled)

12. The power package according to claim 1, further comprising:
a top substrate; and
at least one power die arranged under the top substrate.

13. The power package according to claim 12, wherein the top substrate and the at least one power die are configured in an arrangement configured to provide topside cooling.

14. (canceled)

15. The power package according to claim 12, further comprising a source interconnect configured to be electrically connected to a source of at least one power die.

16. The power package according to claim 15, wherein the source interconnect is connected to at least one of the first power terminals and/or at least one of the second power terminals.

17. The power package according to claim 15, further comprising risers arranged on the at least one power die, wherein the risers are configured to be electrically connected the source interconnect.

18. The power package according to claim 12, wherein the assembly comprises a configuration that is encapsulated in epoxy, overmolded, overmolded with epoxy, and/or potted, potted with a dielectric material.

19. The power package according to claim 12, wherein one of the first power terminals and the second power terminals are configured to connect to the top substrate.

20. The power package according to claim 19, wherein another one of the first power terminals and the second power terminals are configured to connect to the at least one power die.

21. The power package according to claim 12, further comprising an insulation layer arranged on the top substrate,
wherein at least one of the first signal terminals is arranged on the insulation layer; and
wherein at least one of the second signal terminals is arranged on the insulation layer.

22. The power package according to claim 12, further comprising:
at least one signal interconnect,
wherein an implementation of the at least one signal interconnect is connected to at least two of the first signal terminals; and
wherein an implementation of the at least one signal interconnect is connected to at least two of the second signal terminals.

23. The power package according to claim 1,
wherein the first power terminals comprise a first power terminal, a second power terminal, a third power terminal, and a fourth power terminal; and
wherein the second power terminals comprise a first power terminal, a second power terminal, a third power terminal, and a fourth power terminal.

24. A configuration comprising at least one implementation of the power package according to claim 1, wherein the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration.

25.-31. (canceled)

32. A power package comprising:
an assembly comprising a first power package side, a second power package side, a third power package side, and a fourth power package side;
first power terminals arranged at the first power package side;
second power terminals arranged at the second power package side;
first signal terminals arranged at the third power package side; and
second signal terminals arranged at the fourth power package side,
wherein a location of the first signal terminals on third power package side is symmetrical with respect to a location of the second signal terminals on fourth power package side.

33.-54. (canceled)

55. A configuration comprising at least one implementation of the power package according to claim 32, wherein the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration.

56.-57. (canceled)

58. The power package according to claim 32, wherein a location of the first power terminals at the first power package side is symmetrical with respect to a location of the second power terminals at the second power package side.

59.-62. (canceled)

63. A power package comprising:
an assembly comprising a first power package side, a second power package side, a third power package side, and a fourth power package side;
first power terminals arranged at the first power package side;
second power terminals arranged at the second power package side;
first signal terminals arranged at the third power package side; and
second signal terminals arranged at the fourth power package side,
wherein a location of the first signal terminals on third power package side is symmetrical with respect to one side of third power package side and another side of third power package side; and
wherein a location of the second signal terminals on fourth power package side is symmetrical with respect to one side of fourth power package side and another side of fourth power package side.

64.-85. (canceled)

86. A configuration comprising at least one implementation of the power package according to claim 63, wherein the configuration of the at least one implementation of the power package being configured, structured, arranged, and/or implemented such that the configuration implements a standalone configuration, a paralleled configuration, a common-source configuration, a common-drain configuration, a common-source bidirectional configuration, and/or a common-drain bidirectional configuration.

87.-279. (canceled)
